(19) United States
(12) Patent Application Publication
(10) Pub. No.: US 2013/0026917 A1
(43) Pub. Date: Jan. 31, 2013

(54) ION FOCUSING IN A HALL EFFECT THRUSTER

(71) Applicants: Mitchell L.R. Walker, Mableton, GA (US); Kunning Gabriel Xu, Atlanta, GA (US)

(72) Inventors: Mitchell L.R. Walker, Mableton, GA (US); Kunning Gabriel Xu, Atlanta, GA (US)

(21) Appl. No.: 13/560,775

(22) Filed: Jul. 27, 2012

Related U.S. Application Data
(60) Provisional application No. 61/513,519, filed on Jul. 29, 2011.

(51) Int. Cl. H01J 37/16; H01J 9/00; H01J 27/20

(52) U.S. Cl. 315/85; 315/111.81; 315/111.91; 445/23

(57) ABSTRACT

A Hall effect thruster with an annular discharge channel that includes inner and outer sidewall electrodes located at an axial position that is downstream from the anode. The Hall effect thruster may also include shielding elements configured to shield the inner and outer sidewall electrodes from electrons in the annular discharge channel. The shielding elements may be magnetic shielding elements.

### CROSS-REFERENCE TO RELATED APPLICATIONS

This application claims priority to U.S. Provisional Patent Application No. 61/513,519, filed Jul. 29, 2011, and entitled “ION FOCUSING IN HALL EFFECT THRUSTER,” which is incorporated herein by reference in its entirety.

### BACKGROUND

1. Field

The field of the invention generally relates to Hall effect thrusters. More particularly, embodiments of the invention relate to ion focusing by using sidewall electrodes and magnetic barriers in Hall effect thrusters.

2. Description of the Related Art

Electric propulsion (EP) systems are typically used on satellites mainly for orbit station keeping, where the higher exit velocity of EP systems produces a higher specific impulse, which reduces the propellant mass needed for a given mission impulse. It is also possible to use EP systems for orbit transfers, though doing so may have associated disadvantages in some cases. For example, an EP device typically has much lower thrust than a chemical rocket system, which significantly increases the transfer time. For a Hall effect thruster (HET), the thrust and efficiency generally increase with discharge voltage, while the thrust-to-power (T/P) ratio decreases. Increasing the T/P ratio of a HET could provide increased thrust while maintaining good efficiency.

### SUMMARY

In some embodiments, a Hall effect thruster comprises: an annular discharge channel comprising an inner sidewall radially separated from an outer sidewall; an anode provided within the annular discharge channel; an inner sidewall electrode located at an axial position that is downstream from the anode; and an outer sidewall electrode located at an axial position that is downstream from the anode. The Hall effect thruster may further comprise a first shielding element configured to shield the inner sidewall electrode from electrons in the annular discharge channel, and a second shielding element configured to shield the outer sidewall electrode from electrons in the annular discharge channel. The first and second shielding elements may comprise first and second magnetic shielding elements.

### BRIEF DESCRIPTION OF THE DRAWINGS

Various embodiments and features of devices, systems, and methods will be described with reference to the following drawings. The drawings, associated descriptions, and specific implementation are provided to illustrate embodiments of the invention and not to limit the scope of the disclosure.

FIG. 1 is a cross-sectional schematic representation of a Hall effect thruster whose discharge channel includes sidewall electrodes;

FIG. 2 is a cross-sectional schematic representation of a Hall effect thruster whose discharge channel includes sidewall electrodes that are at least partially shielded from electrons by magnetic fields;

FIG. 3 is a cross-sectional schematic representation of the magnetic fields within the discharge channel of a Hall effect thruster that includes magnetically-shielded sidewall electrodes;

FIG. 4 is a cross-sectional schematic representation of a Hall effect thruster that illustrates first and second electromagnets for magnetically-shielding sidewall electrodes in the discharge channel;

FIG. 5 illustrates a perspective view of a magnetic flux guide for a Hall effect thruster;

FIG. 6 is a schematic representation of a discharge power electrical circuit for powering the cathode and anode of a Hall effect thruster, as well as an electrode power electrical circuit for powering sidewall electrodes in the discharge channel;

FIG. 7 is a graph illustrating the thrust-to-power ratio of a Hall effect thruster having magnetically-shielded sidewall electrodes, where the thrust-to-power ratio is plotted as a function of discharge voltage at a constant discharge current for four different sidewall electrode voltages;

FIG. 8 is a graph illustrating the thrust-to-power ratio of a Hall effect thruster having magnetically-shielded sidewall electrodes, where the thrust-to-power ratio is plotted as a function of discharge voltage for combinations of two different discharge currents and two different sidewall electrode voltages;

FIG. 9 is a cross-sectional schematic representation of the magnetic fields within the discharge channel of a Hall effect thruster that includes magnetically-shielded sidewall electrodes, where the shielding magnetic circuit for the left-hand example does not include a flux ring, while the right-hand example does include a flux ring;

FIG. 10 is a graph illustrating the magnitude of the radial component of the magnetic field at the center line of the discharge channel of a Hall effect thruster as a function of distance from the anode for the two examples of magnetic fields illustrated in FIG. 9;

FIG. 11 is a cross-sectional schematic representation of the magnetic fields within the discharge channel of a Hall effect thruster that includes magnetically-shielded sidewall electrodes, where the shielding magnetic circuit has been improved in some respects as compared to those illustrated in FIG. 9;

FIG. 12 is a graph illustrating the magnitude of the radial component of the magnetic field at the center line of the discharge channel of a Hall effect thruster as a function of distance from the anode for the magnetic fields illustrated in FIG. 11;

FIG. 13 is a schematic representation of a vacuum test facility used to test embodiments of the Hall effect thrusters described herein;

FIGS. 14A and 14B include graphs of thrust, thrust-to-power ratio, specific impulse, and anode efficiency all plotted as functions of discharge voltage at four different sidewall electrode voltages for a Hall effect thruster using one embodiment of magnetically-shielded sidewall electrodes;

FIGS. 15A and 15B include graphs of thrust, thrust-to-power ratio, specific impulse, and anode efficiency all plotted as functions of discharge voltage at four different sidewall electrode voltages for a Hall effect thruster using another embodiment of magnetically-shielded sidewall electrodes;

FIGS. 16A and 16B include graphs similar to those shown in FIGS. 15A and 15B, except that the Hall effect thruster was operated at a higher discharge current;

FIGS. 17A and 17B include graphs similar to those shown in FIGS. 15A and 15B, except that xenon was used as the propellant for the Hall effect thruster instead of krypton;

FIG. 18 is a graph of thrust plotted as a function of discharge voltage at four different sidewall electrode voltages in a Hall effect thruster using two different embodiments of magnetically-shielded sidewall electrodes;

FIG. 19 is an illustration of a Hall effect thruster having electrodes embedded within the inner and outer sidewalls of the discharge channel;

FIG. 20 is a close-up photograph of a Hall effect thruster similar to that illustrated in FIG. 19, which better illustrates the electrodes embedded within the inner and outer sidewalls of the discharge channel;

FIG. 21 is a schematic representation of another vacuum test facility used to test embodiments of the Hall effect thrusters described herein;

FIG. 22 is a schematic representation of a Faraday probe that can be used to measure ion density in the plume of a Hall effect thruster;

FIG. 23 is a photograph of the Faraday probe of FIG. 22;

FIG. 24 is a schematic representation of a Retarding Potential Analyzer that can be used to measure ion energies in the plume of a Hall effect thruster;

FIG. 25 is a photograph of the Retarding Potential Analyzer of FIG. 24;

FIG. 26 is a graph of thrust plotted as a function of discharge voltage in an embedded electrode Hall effect thruster with krypton propellant for various sidewall electrode voltages;

FIG. 27 is a graph of the thrust-to-power ratio plotted as a function of discharge voltage in an embedded electrode Hall effect thruster with krypton propellant for various sidewall electrode voltages;

FIG. 28 is a graph of specific impulse plotted as a function of discharge voltage in an embedded electrode Hall effect thruster with krypton propellant for various sidewall electrode voltages;

FIG. 29 is a graph of efficiency plotted as a function of discharge voltage in an embedded electrode Hall effect thruster with krypton propellant for various sidewall electrode voltages;

FIG. 30 is a graph of thrust plotted as a function of discharge voltage in an embedded electrode Hall effect thruster with xenon propellant for various sidewall electrode voltages;

FIG. 31 is a graph of thrust-to-power ratio plotted as a function of discharge voltage in an embedded electrode Hall effect thruster with xenon propellant for various sidewall electrode voltages;

FIG. 32 is a graph of specific impulse plotted as a function of discharge voltage in an embedded electrode Hall effect thruster with xenon propellant for various sidewall electrode voltages;

FIG. 33 is a graph of efficiency plotted as a function of discharge voltage in an embedded electrode Hall effect thruster with xenon propellant for various sidewall electrode voltages;

FIGS. 34A-D are graphs of ion current density plotted as a function of angular position for an embedded electrode Hall effect thruster operating with different discharge voltages and using various sidewall electrode voltages;

FIGS. 35A-D are graphs that show magnified views of portions of the graphs shown in FIGS. 34A-D;

FIGS. 36A-D are graphs of the normalized current densities shown in FIGS. 34A-D;

FIG. 37 is a graph of ion beam current plotted as a function of discharge voltage in an embedded electrode Hall effect thruster for various sidewall electrode voltages;

FIG. 38 is a graph of propellant mass flow rate plotted as a function of discharge voltage in an embedded electrode Hall effect thruster for various sidewall electrode voltages;

FIG. 39 is a graph of propellant efficiency plotted as a function of discharge voltage in an embedded electrode Hall effect thruster for various sidewall electrode voltages;

FIG. 40 is a graph of plume half angle plotted as a function of discharge voltage in an embedded electrode Hall effect thruster for various sidewall electrode voltages;

FIGS. 41A-D are graphs of ion energy distribution and current plotted as a function of sweep voltage in an embedded electrode Hall effect thruster at different angles and for various sidewall electrode voltages;

FIG. 42 is a graph of ion energy plotted as a function of discharge voltage in an embedded electrode Hall effect thruster for various sidewall electrode voltages;

FIG. 43 is a graph of ion energy plotted as a function of angular position in an embedded electrode Hall effect thruster for various sidewall electrode voltages;

FIGS. 44A-C are illustrations showing electric potential contour lines in an embedded electrode Hall effect thruster for various sidewall electrode voltages;

FIG. 45 is an illustration showing electric potential contour lines in an embedded electrode Hall effect thruster for a selected sidewall electrode voltage;

FIG. 46 is a graph of electric potential plotted as a function of distance from the anode in an embedded electrode Hall effect thruster for various sidewall electrode voltages;

FIG. 47 is a graph of the electric field strength plotted as a function of distance from the anode in an embedded electrode Hall effect thruster for various sidewall electrode voltages; and

FIG. 48 is a graph of electrode current plotted as a function of discharge voltage in an embedded electrode Hall effect thruster for various sidewall electrode voltages.

### DETAILED DESCRIPTION

### I. Introduction

A Hall effect thruster (HET) is a type of ion thruster device that creates thrust by accelerating a propellant using an electric field. A HET may include an annular discharge channel made up of an inner sidewall that is radially separated from an outer sidewall, both sidewalls extending in an axial direction. A propellant, such as an electrically-neutral inert gas (e.g., xenon or krypton), is introduced at an upstream axial end of the discharge channel. The atoms of the propellant are ionized within the discharge channel, and thrust is created by expelling the ions from the downstream axial end of the discharge channel at high velocity.

In a HET, a cathode can be used to provide electrons in the vicinity of the exit plane of the discharge chamber. In conjunction with the cathode and the electrons, an anode located upstream creates an axial electric field that accelerates propellant ions in the axial direction of the discharge chamber. Meanwhile, a magnetic circuit is provided to create a radial magnetic field downstream from the anode within a portion of the discharge chamber between the inner and outer sidewalls. The combination of the radial magnetic field and the axial electric field has the effect of causing the electrons from the cathode to travel around the annular discharge chamber azimuthally, forming a Hall current.

The propellant is injected into the discharge chamber at the upstream axial end of the chamber. The neutral propellant atoms become ionized by collisions with the circulating electrons in the Hall current. Once the propellant atoms have been ionized, they are accelerated by the axial electric field formed between the anode and the circulating electrons. The accelerated ions are then ejected from the discharge chamber at its downstream axial end, thus creating thrust.

A goal of high thrust-to-power (T/P) ratio technology in a HET is to create a bimodal HET. In high thrust, low specific impulse mode, the thruster can be used to perform, for example, the low-Earth orbit (LEO) to geosynchronous Earth orbit (GEO) transfer. The low thrust, high specific impulse mode can allow the same thruster to perform, for example, station-keeping. The end result is a single EP device that is capable of performing both orbit transfers and station-keeping efficiently. This can result in a significant mass savings in a space vehicle due to the removal of the chemical orbit transfer engine.

A HET may use relatively low discharge voltage and relatively high discharge current to achieve a high T/P ratio. As the discharge current of a HET increases, the number of propellant ions lost to the discharge channel sidewalls (e.g., by neutralizing collisions with the sidewalls) may also increase. Ions are the thrust producing particles in a HET, and, thus, the loss of any ions before they exit the thruster results in an efficiency loss. Thus, one way to increase thruster efficiency at high current densities is to reduce ion neutralization collisions with the discharge channel sidewalls. Reduction of ion collisions with the discharge chamber's sidewalls can be accomplished, for example, through the use of an ion focusing technique in the discharge chamber. The ion focusing technique can guide ions with trajectories that would have otherwise intersected with the discharge chamber wall toward the center of the discharge channel resulting in an increase in the TIP ratio of the HET. This increase can result both from increasing the number of ions ejected from the discharge chamber (by reducing the number of ions that are lost to neutralization after impact with the discharge chamber sidewalls) and by reducing the radial component of velocity of the discharged ions.

Section II presents the theory of ion loss reduction. Section III gives the experimental setup used in a study. Section IV presents the results of performance tests done using the first set of sidewall electrodes that are described herein. Section V presents the modifications made to the thruster to incorporate embedded electrodes, as described herein. Section VI presents the diagnostics used to measure the embedded electrode Hall effect thruster (EEHET) to test the embedded electrode design. Section VII discusses the performance results and plasma measurements of the EEHET. Section VIII summarizes the work.

### II. Ion Loss Reduction

### Theory of Operation

High T/P operation may use, for example, relatively low discharge voltage between the anode and cathode and relatively high discharge current of expelled ions. As discharge current increases, more ions are produced and a larger number of ions impact the channel wall and self neutralize. The neutralized ions are not affected by the static axial electric field and, thus, are not accelerated to produce thrust. To increase the thrust density of a HET and achieve the high T/P goals, it is advantageous to reduce the number of ions lost to the discharge channel walls.

In some embodiments, a solution is to incorporate positively-charged electrodes along at least a portion of the discharge channel sidewalls, for example, near the ionization zone, to repel ions away from the sidewalls. Such an arrangement will result in electric fields that not only repel ions from the channel walls, but in addition help to focus ions toward the centerline. FIG. 1 shows a notional schematic of this concept

FIG. 1 is a cross-sectional schematic representation of a Hall effect thruster 100 whose discharge channel 108 includes sidewall electrodes 110, 112. The Hall effect thruster 100 includes sidewalls 102, 104 that extend in an axial direction. Sidewalls 102, 104 are separated in a radial direction, forming a discharge channel 108 between the two sidewalls. An anode 106 is provided at an upstream portion of the discharge channel 108. It should be understood that the discharge channel 108 is annular and that FIG. 1 is a sectional view through only a portion of the annular channel. In FIG. 1, sidewall 104 can be understood, for example, as the radially-inward sidewall of the discharge channel 108, while sidewall 102 can be understood as the radially-outward sidewall of the discharge channel 108. In addition, it should be understood that the Hall effect thruster can also include components such as a cathode provided at the downstream axial end of the thruster 104 to provide electrons into the downstream end of the discharge channel 108, a magnetic circuit for providing a radial magnetic field between the sidewalls 102, 104 near the exit plane of the thruster, a power system, a propellant system, a controller, etc.

With reference to FIG. 1, the radial magnetic field lines (not illustrated) extend generally vertically between the sidewalls 102, 104, while the axial electric field lines (illustrated only in combination with the electric field lines that result from the sidewall electrodes 110, 112) generated by the anode extend relatively horizontally. Electrons injected by the cathode are forced into a Hall current flowing into or out of the page depending upon the polarity of the radial magnetic field.

As noted above, the Hall thruster 100 includes sidewall electrodes 110, 112. The sidewall electrodes 110, 112 can be made out of, for example, graphite, carbon composites, any refractory metal, combinations of the same, or the like. In some embodiments, the sidewall electrodes 110, 112 are provided within the interior of the discharge channel 108. In other embodiments, the sidewall electrodes 110, 112 are partially or wholly embedded within the sidewalls 102, 104 of the thruster 100 in order to reduce or eliminate their physical presence in the discharge channel 108, as discussed herein. The sidewall electrode 112 can be, for example, an annular ring provided about the inner sidewall 104 of the annular discharge channel 108. The sidewall electrode 110 can be, for example, a larger-diameter annular ring provided about the outer sidewall 102 of the annular discharge channel 108. In some embodiments, the sidewall electrodes 110, 112 extend continuously about the inner and outer sidewalls, respectively, of the annular discharge channel 108. Alternatively, the sidewall electrodes 110, 112 could be segmented. In some embodiments, the sidewall electrodes 110, 112 have a square or rectangular cross-sectional shape, though other shapes could also be used.

The sidewall electrodes 110, 112 can be positioned axially along the discharge channel 108 between the anode and the exit plane of the thruster 100. In some embodiments, the sidewall electrodes 110, 112 are positioned at an axial location that is between the anode 106 and the ionization zone within the discharge channel 108. In some embodiments, the sidewall electrodes 110, 112 are positioned at an axial location that is upstream from the peak magnitude of the radial magnetic field that produces the Hall current.

As illustrated in FIG. 1, the sidewall electrodes 110, 112 can be biased to a positive voltage. For example, the sidewall electrodes 110, 112 can be biased to a positive voltage that is higher than the positive voltage to which the anode 106 is biased. Thus, in some embodiments, different portions of, or structures within, the discharge channel 108 are biased to at least two different electrical potentials. In some embodiments, the sidewall electrodes 110, 112 are biased to a positive voltage that is, for example, at least 5 V above the anode voltage. In some embodiments, the sidewall electrodes 110, 112 are biased to a positive voltage that is at least 10 V above the anode voltage. In some embodiments, the sidewall electrodes 110, 112 are biased to a positive voltage that is 10-30 V above the anode voltage. Other voltages may also be used. In some embodiments, the sidewall electrodes 110, 112 are both biased to the same voltage. As illustrated in FIG. 1, the addition of the positively-charged sidewall electrodes 110, 112 modifies the electric field lines within the discharge channel 108, adding somewhat radial components to the electric field lines in the vicinity of the electrodes. These radial components of the electric field help to force propellant ions away from the sidewalls 102, 104 of the discharge channel 108. In addition, the electric field from the sidewall electrodes 110, 112 can improve focusing of the expelled propellant ions along the center line of the discharge channel 108.

The positively-charged sidewall electrodes 110, 112 will attract electrons, however. Electrons escape from the Hall current by jumping magnetic field lines as they change energy through collisions with other particles and the thruster walls. These electrons will travel along electric field lines straight to the unprotected positively-charged electrodes 110, 112. Electrons that make it to the sidewall electrodes 110, 112 are no longer available for ionization and decrease the amount of power available to create thrust, which decreases the efficiency of the device. Therefore, in some embodiments, the sidewall electrodes 110, 112 are shielded from electrons. In some embodiments, the sidewall electrodes 110, 112 are magnetically shielded using additional magnetic fields, as discussed herein. However, in some embodiments, the sidewall electrodes 110, 112 are shielded from electrons in the discharge channel 108 by, for example, a physical layer of electrically insulating material or by any other appropriate means.

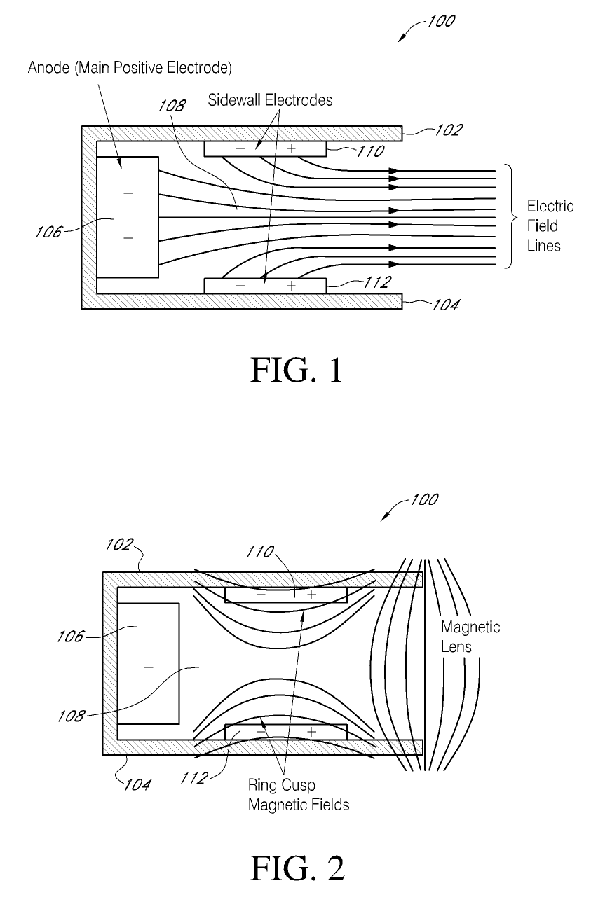

FIG. 2 is a cross-sectional schematic representation of a Hall effect thruster 100 whose discharge channel 108 includes sidewall electrodes 110, 112 that are at least partially shielded from electrons by magnetic fields 120, 122. The shielding magnetic fields 120, 122 can have some components that are, for example, perpendicular to the surface normals of the sidewall electrodes 110, 112, as illustrated in FIG. 2. The shielding magnetic fields 120, 122 can be generated by, for example, electromagnets that are located outside of the discharge channel 108 but adjacent to the sidewalls 102, 104. For example, the shielding magnetic fields 122 can be generated by at least one electromagnet that is located in the center portion of the thruster 100 between the inner sidewalls 104 of the annular discharge channel 108 (only one of which is illustrated in FIG. 2). This electromagnet can include, for example, loops of magnetic wire provided in a c-channel that loops around the inner sidewall 104 and whose opening faces the inner sidewall 104. Similarly, the shielding magnetic fields 120 can be generated by an electromagnet that is located at the outer portion of the thruster 100, radially beyond the outer sidewall 102. This electromagnet, too, can include, for example, loops of magnetic wire provided in a larger-diameter looped c-channel whose opening faces the outer sidewall 102.

FIG. 2 shows the use of ring-cusp magnetic fields 120, 122, placed around the positively-charged electrodes, acting as barriers to electrons. The ring-cusp technique can be, for example, similar to that used in the ionization chamber of ion engines. Electrons guided to the electrodes by the electric field encounter magnetic field lines perpendicular to the electrode surface normal vector. The electrons are magnetized and prevented from reaching the electrodes, which reduces the flux of electron to the electrodes.

The magnetic fields 120, 122 can have the same or opposite polarities. The polarities of the shielding magnetic fields 120, 122 within the discharge channel 108 can be, for example, generally in the upstream direction or the downstream direction. However, other orientations are also possible. In some embodiments, the magnitude of the shielding magnetic fields 120, 122 is less than the magnitude of the main, radial magnetic field that generates the Hall current within the thruster 100. For example, the shielding magnetic fields 120, 122 can be about 50% as strong as the radial magnetic field, or weaker. In some embodiments, the polarities and magnitudes of the shielding magnetic fields 120, 122 can be configured so as to deflect electrons that are traveling radially towards the sidewall electrodes 110, 112 so that they began traveling azimuthally around the annular discharge channel 108, for example, along the same direction as the Hall current.

Work done on this project includes an initial version 1 design of the shielding magnetic fields, modification of an existing thruster to incorporate the stainless steel sidewall electrodes 110, 112 and ring-cusp magnets, testing of the version 1 design, redesign of the shielding magnetic fields for version 2, and a test of the version 2 design. That work will be summarized here.

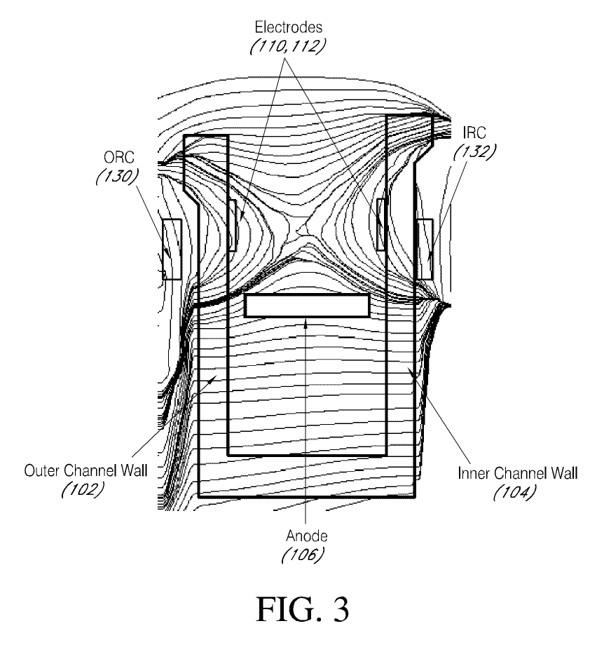

A tenant of this research is reduction of the electron current collected by the in-channel electrodes 110, 112 due to the electrodes' positive bias. In some, but not necessarily all, embodiments, ring-cusp magnetic fields are employed for this purpose, as discussed herein. Owing to introduction of these magnetic fields for shielding the sidewall electrodes 110, 112, the thruster design can benefit from a magnetic field study to determine how best to accomplish the desired magnetic shielding. The finite element software MagNet, by Infolytica was used to model the thruster and the resulting magnetic field. A final magnetic field topology was obtained for version 1, as shown in FIG. 3.

FIG. 3 is a cross-sectional schematic representation of the magnetic fields within the discharge channel of a Hall effect thruster that includes magnetically-shielded sidewall electrodes. FIG. 3 illustrates the discharge channel, inner and outer channel sidewalls 102, 104, and anode 106, as discussed herein. FIG. 3 also illustrates the sidewall electrodes 110, 112 and the inner ring-cusp (IRC) and the outer ring-cusp (ORC) shielding electromagnets 130, 132, as also discussed herein. The illustrated magnetic field design places the sidewall electrodes 110, 112 in approximately the center of the cusp fields, providing relatively good shielding. This was accomplished by removing the back piece of the flux guide (illustrated in FIG. 5) used to complete the magnetic circuit. While the illustrated magnetic design provides relatively good shielding of the electrodes, it would later be learned that the illustrated magnetic field created a mirror point in the channel which can decrease thrust. Thus, the magnetic field was redesigned for version 2. After the version 1 field was finalized, the thruster (a Pratt & Whitney T-220HT) was physically modified. It should be understood, however, that a variety of channel magnetic field configurations, and magnetic circuits used to provide such magnetic field configurations, can be used in different embodiments depending upon design criteria for a particular application.

### Physical Modifications

In version 1 embodiment, the positively-charged electrodes that line both the inner and outer discharge channel walls are made out of 1/16 in. thick by 0.4 in. wide stainless-steel strips. Stainless steel was used because of its resistance to magnetization and high heat tolerance. The electrodes are positioned substantially in the middle of the ring-cusp magnetic fields. The electrodes are affixed to small stainless-steel rods that are inserted into holes drilled through the back of the discharge channel and attached to the thruster bracket behind the channel. Ceramic sleeves insulate the high-voltage rods from the thruster body and ambient plasma.

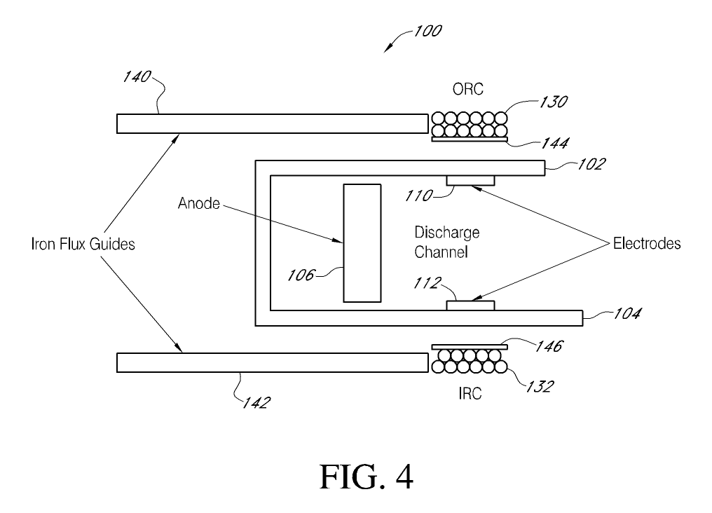

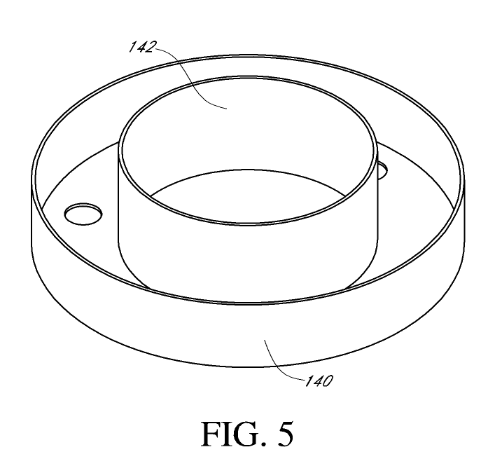

FIG. 4 is a cross-sectional schematic representation of a Hall effect thruster 100 that illustrates first and second electromagnets IRC 132, ORC 130 for magnetically-shielding sidewall electrodes 112, 110 in the discharge channel, as discussed herein. FIG. 4 shows an approximate configuration for the changes made to the T-220HT. The outer ring-cusp (ORC) 130 and inner ring-cusp (IRC) 132 electromagnets use, for example, 13-AWG, single strand, fiberglass-coated magnet wire—12 turns for the outer magnet and 11 turns for the inner magnet. The ferromagnetic iron flux guide 140, 142 is shaped to focus the magnetic field lines to assist in the production of the ring-cusp coils. As discussed herein, the iron flux guide 140, 142 may include, for example, one or more c-channels in which the ORC 130 and the IRC 132 are provided. Thin stainless-steel metal sheets 144, 146 can be used to shield the electromagnet wire from the hot sidewalls of the channel.

FIG. 5 illustrates a perspective view of the original magnetic flux guide for the T-220HT Hall effect thruster. The original flux guide was replaced without the bottom ring, resulting in a flux guide having concentric cylinders, as illustrated in FIG. 4.

### Electrical Considerations

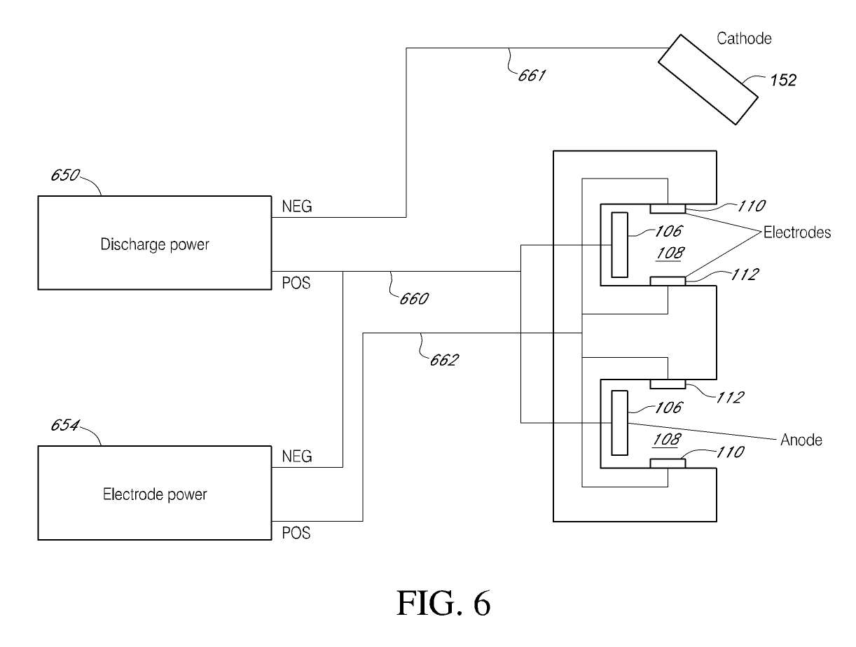

FIG. 6 is a schematic representation of a discharge power electrical circuit for powering the cathode 152 and anode 106 of a Hall effect thruster, as well as an electrode power electrical circuit for powering sidewall electrodes 110, 112 in the discharge channel 108. The discharge channel 108, anode 106, and sidewall electrodes 110, 112 can be, for example, as discussed herein with respect to the foregoing figures.

The addition of the electrode pair 110, 112 generates an interesting electrical issue. In some embodiments, both electrodes 110, 112 are tied to a common electrical line 662, which is connected to the positive side of the electrode power supply 654, so that they are biased to the same electrical potential. The bias voltage of the sidewall electrodes, provided by the electrode line 662, is above the plasma potential, however, so that the ions are affected. In some embodiments, in order to accomplish this, the negative side of the electrode power supply 654 is tied into the anode line 660, which is also the positive side of the discharge supply 650, as shown in FIG. 6. This allows the electrodes 110, 112 to float at the plasma potential. The electrode power supply 654 can also be plugged into an isolation transformer to keep it separated from ground.

### Results of Version 1 Embodiment

During testing, the modified thruster ran at constant current levels, 6.1 A, 9.1 A, and 11.9 A, at discharge voltages ranging from 100-300 V, and mass flow rates to achieve the constant current level, typically in the range 5-15 mg/s of xenon. The thruster was run at constant current to simulate similar conditions in other high T/P HETs. The thruster went through a series of four tests. The first two tests of the modified thruster were without and with the modifications described herein in use. This was compared to historical data to determine what effects the physical modifications have on the performance. The results showed good adherence to historical trends with some larger deviations at low voltages. However there is a dearth of historical data available at low voltages, thus the magnitude of any deviations are hard to quantify.

The third test varied the ring cusp magnet current to identify an optimal operating condition. A setting was identified as providing the best T/P ratio and used on subsequent tests. The final set of tests measured the performance over varied discharge voltages and electrode potentials. The test matrix is shown in Table 1 with discharge voltages in the middle.

TABLE 1

| | | Discharge Current | | |
|---|---|---|---|---|
| | | 6 A | 9.1 A | 11.9 A |
| Electrode | 10 V | 125-175 V | 100-300 V | 125-175 V |
| Voltage | 20 V | | 100-300 V | |
| | 30 V | 125-175 V | 100-300 V | 125-175 V |

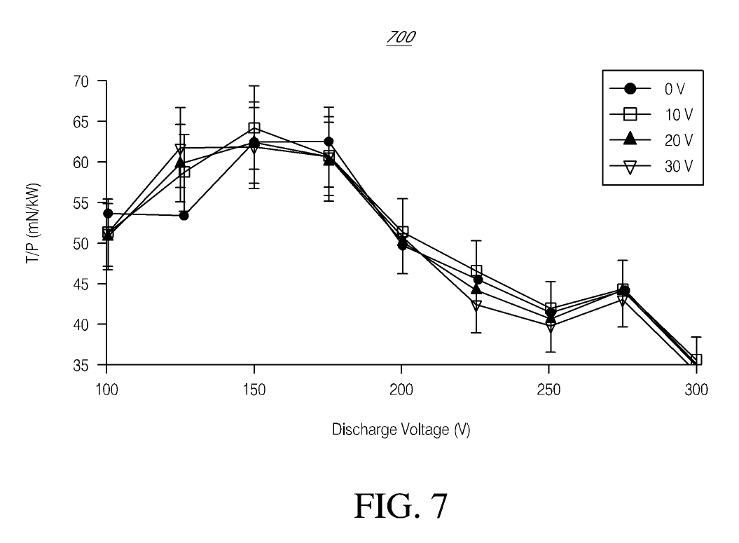

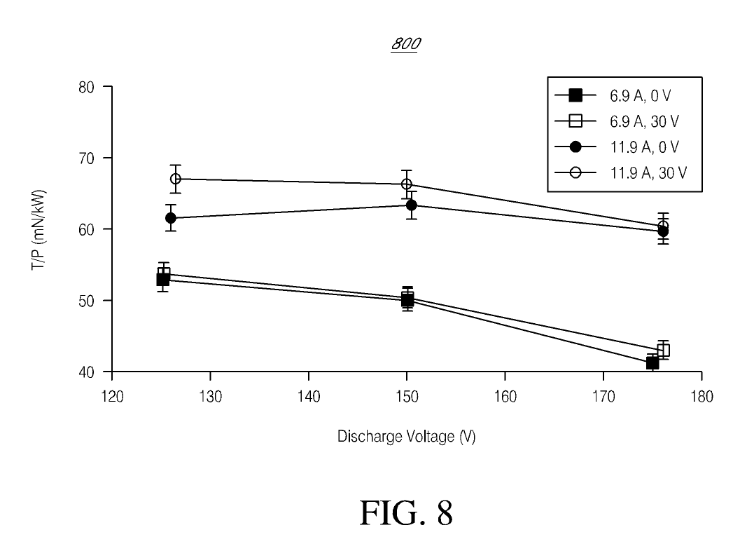

FIG. 7 is a graph 700 illustrating the thrust-to-power ratio of a Hall effect thruster having magnetically-shielded sidewall electrodes, where the thrust-to-power ratio is plotted as a function of discharge voltage at a constant discharge current for four different sidewall electrode voltages. FIG. 8 is a graph 800 illustrating the thrust-to-power ratio of a Hall effect thruster having magnetically-shielded sidewall electrodes, where the thrust-to-power ratio is plotted as a function of discharge voltage for combinations of two different discharge currents and two different sidewall electrode voltages.

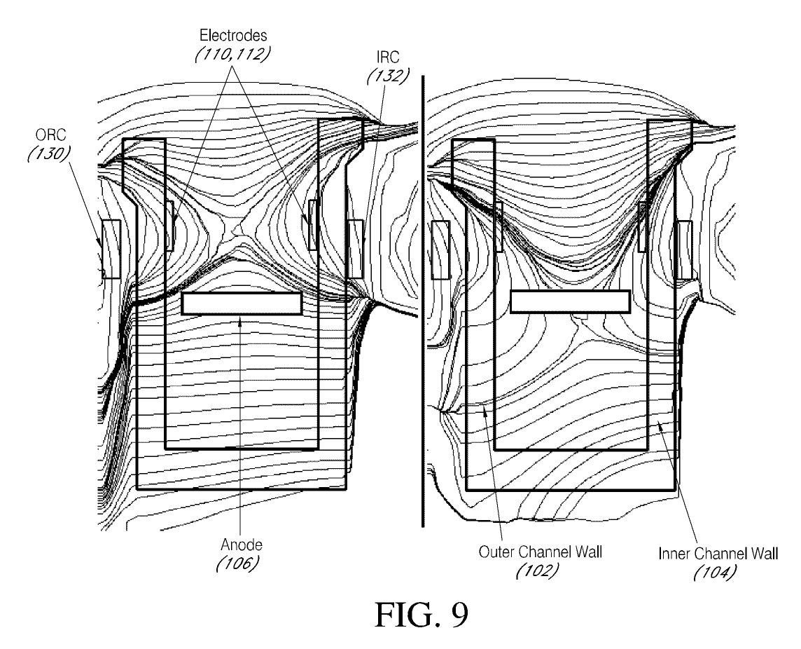

The T/P ratio results are plotted in FIG. 7 for 9.1 A current and FIG. 8 for 6 A and 11.9 A current. The results show some increase in T/P ratio with the electrodes. However, they are somewhat inconsistent. For the majority of the cases, any changes fall within the error range. The concluded reason for this result was the design of the magnetic field. As mentioned earlier, the ring section of the flux guide (shown in FIG. 5), which helps shape the magnetic field, was removed. This allowed better shielding of the electrodes. However, it also created a sub-optimal magnetic field for thrust generation in the particular embodiments being studied. Accordingly, the magnetic field was redesigned for both shielding of the electrodes and thrust generation. One option was to replace the removed flux ring. However, simulations showed that doing so would cause the magnetic field to become asymmetric and would reduce shielding of the electrodes, as shown on the right in FIG. 9.

FIG. 9 is a cross-sectional schematic representation of the magnetic fields within the discharge channel of a Hall effect thruster that includes magnetically-shielded sidewall electrodes, where the shielding magnetic circuit for the left-hand example does not include a flux ring, while the right-hand example does include a flux ring. The configuration with the replaced flux ring would lessen and possibly eliminate the shielding ability of the ring-cusp field. As shown on the right-hand side of FIG. 9, the electrodes are half in the cusp fields, and many field lines intersect the electrodes, which could increase electron current due to electrons riding on magnetic field lines. Thus, for this particular embodiment, the magnetic field illustrated on the right-hand side of FIG. 9 was seen as sub-optimal. However, it was determined that a complete flux guide could be designed to provide a better magnetic field in terms of shielding and thrust generation.

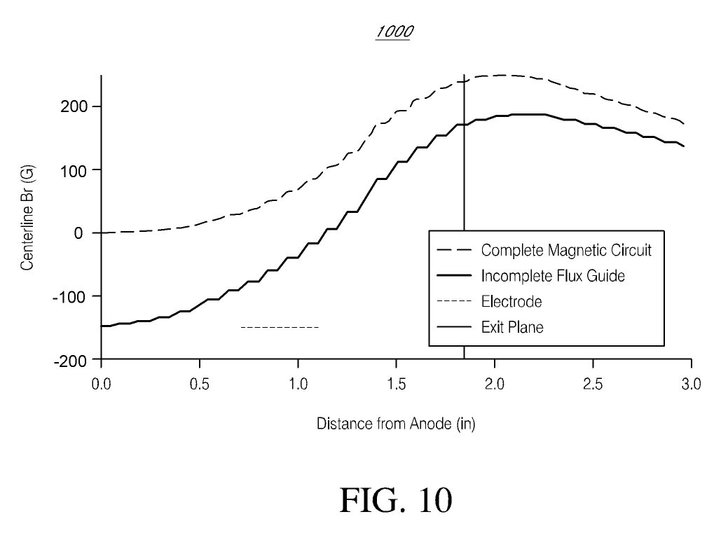

FIG. 10 is a graph 1000 illustrating the magnitude of the radial component of the magnetic field at the center line of the discharge channel of a Hall effect thruster as a function of distance from the anode for the two examples of magnetic fields illustrated in FIG. 9. FIG. 10 shows the radial magnetic field taken at the channel centerline with and without the flux ring. The dashed line shows a complete flux guide, and the field reaches near zero only at the anode. The solid line shows the version 1 field with incomplete flux guide. The field crosses zero field strength approximately halfway along the axial distance of the channel and goes negative. This type of structure is called a magnetic mirror, and can trap electrons between the anode and exit plane of the discharge channel. The trapped electrons have a harder time reaching the anode to complete the electrical circuit, which can decrease performance. The graph 1000 shows that a complete flux guide was more suitable for the particular embodiment under study, and, thus, a complete field redesign was done.

### Magnetic Circuit Redesign

A major effort to redesign the magnetic circuit was undertaken to improve the performance of the thruster. There were four goals of the redesign:

1) Achieve a near-zero magnitude of Bᵣ at the anode face

2) Shield the pair of in-channel electrodes

3) Maintain a generally symmetric magnetic field downstream of the anode

4) Create a generally flat plasma lens

A lower Bᵣ at the anode face will move the mirror point of the magnetic field closer to the anode, which enhances electron mobility to the anode to complete the electrical circuit. Furthermore, a generally symmetric magnetic field and generally flat plasma lens will lead to improvements in thruster performance.

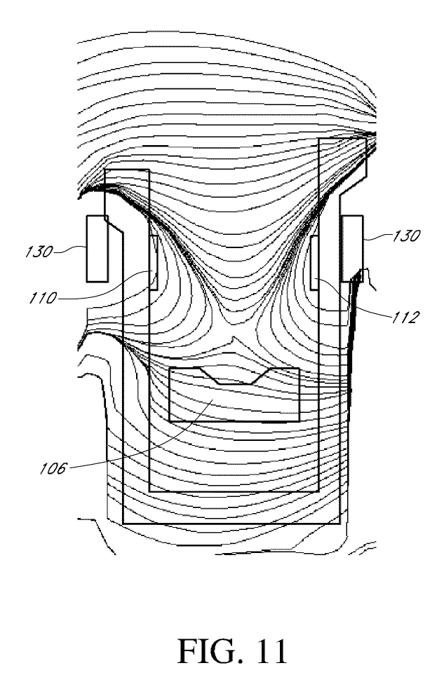

The final solution meets all four goals, and only involves the fabrication of four parts: flux guide, center magnet pole, center magnet return, and a modification to the discharge channel. FIG. 11 shows the resulting channel magnetic field topography. Specifically, FIG. 11 is a cross-sectional schematic representation of the magnetic fields within the discharge channel of a Hall effect thruster that includes magnetically-shielded sidewall electrodes, where the shielding magnetic circuit has been improved in some respects as compared to those illustrated in FIG. 9. The magnetic field illustrated in FIG. 11 exhibits the relatively good magnetic shielding of the sidewall electrodes that is somewhat similarly exhibited by the magnetic design in the left-hand portion of FIG. 9. In addition, the magnetic field illustrated in FIG. 11 exhibits a reduced magnetic mirror effect, as somewhat similarly exhibited by the magnetic design in the right-hand portion of FIG. 9.

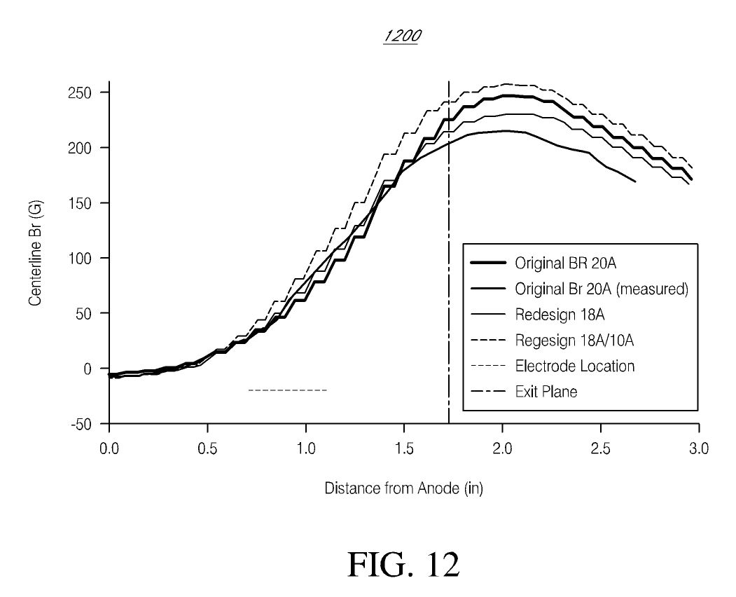

FIG. 12 is a graph 1200 illustrating the magnitude of the radial component of the magnetic field at the center line of the discharge channel of a Hall effect thruster as a function of distance from the anode for the magnetic fields illustrated in FIG. 11. FIG. 12 shows the centerline Bᵣ for the new design compared to the original thruster. A total of four sets of curves are shown. The first two curves, as shown in the legend, are the simulated and measured field for the original, unmodified T-220HT. The next two curves, as shown in the legend, are the simulated field strength for version 2. The version 2 centerline field falls very close to the original, and the field topology has less of a magnetic mirror, all of which should increase thruster performance.

### III. Experimental Setup

### Vacuum Facility

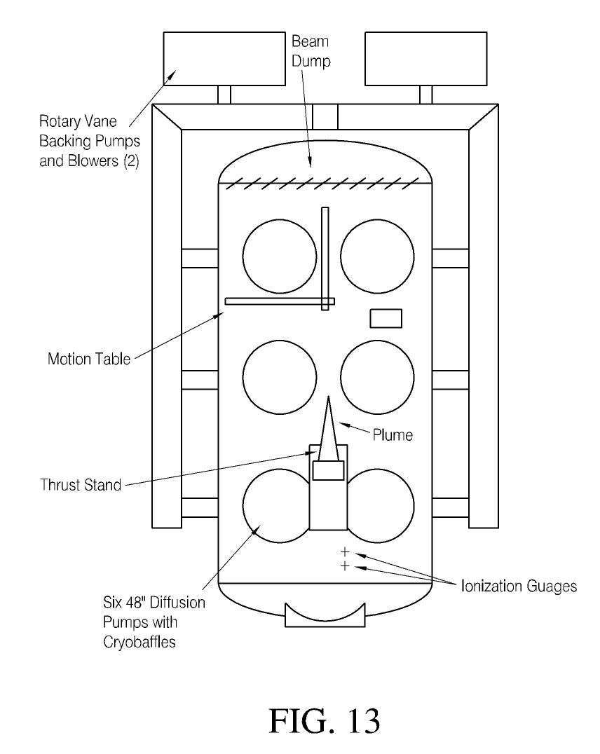

FIG. 13 is a schematic representation of the vacuum test facility used to test embodiments of the Hall effect thrusters described herein. The VTF is a stainless steel vacuum chamber that has a diameter of 4 m and a length of 7 m. The VTF pumping speed is varied by changing the number of diffusion pumps in operation. The combined pumping speed of the facility is 600,000 l/s on air and 155,000 l/s on xenon with a base pressure of 1.2×10⁻⁴ Pa (9.5×10⁻⁷ Torr). At the anode flow rates investigated—1 to 7 mg/s, and at a nominal xenon pumping speed of 155 kl/s, the operating pressures of the VTF range from 1.3×10⁻³ Pa—Xe (1.3×10⁻⁵ Torr-Xe) to 2.6×10⁻³ Pa—Xe (2.6×10⁻⁵ Torr-Xe). Chamber pressure is monitored by a pair of Varian 571 ionization gauges along with a UHV-24 nude gauge all connected to an XGS-600 controller.

### Thrust Stand

The thrust of the modified T-220HT is measured with a high-power null-type inverted pendulum type thrust stand capable of achieving an accuracy of 1% of full scale. The null-type thrust stand holds the thruster at a set position at all thrust levels, which reduces error in the thrust by eliminating changes in the elevation of the thrust vector. In-situ thruster/thrust-stand leveling is performed with a remotely-controlled geared motor coupled to a jackscrew. A remotely-controlled motor driven pulley system is employed to provide in-situ thrust stand calibration by loading and off-loading small weights to simulate thrust. A linear curve-fit of null-coil voltage versus calibrated weight (thrust) is then obtained and used for performance measurements. To maintain thermal equilibrium within the thrust stand at high-power Hall thruster operating conditions, the stand is actively cooled.

Between every six data points, the thruster is shut down and the thrust stand allowed to re-zero itself and a calibration run is performed. There exists a zero drift in the thrust stand, and the cause is undetermined. As the zero drift occurs over the span of 6 test points, it is somewhat difficult to determine whether it is a linear drift, or one time drift, and is, thus, difficult to factor into the data.

### IV. Performance of Version 2 Embodiment

The version 2 design uses the same electrodes as version 1. Two new parts were fabricated to allow proper placement of the magnetic fields. The two parts are the center magnetic pole and the flux guide. Krypton was used as the primary propellant for cost savings, though xenon was used briefly at the end. The full set of thruster performance tests comprised four parts: original electrodes, thick electrodes, high current operation, and finally xenon operation.

### Original Electrodes

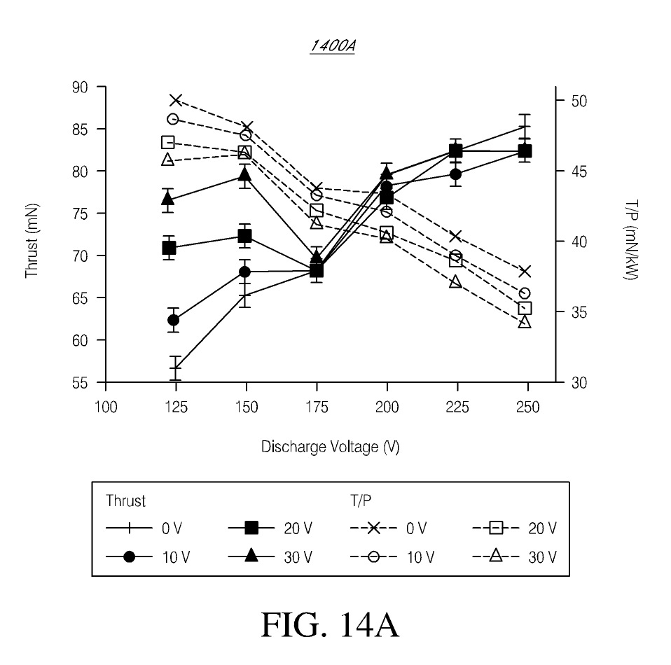

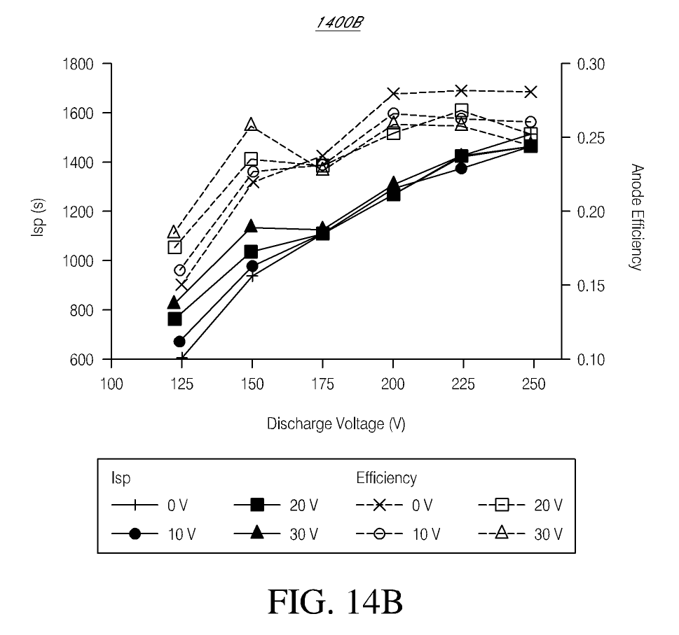

The first test used the same electrodes from the version 1 design, which were stainless steel bands 0.4″ wide and 0.015″ thick. The performance (thrust, Isp, T/P, and efficiency) is shown in FIGS. 14A and 14B.

FIGS. 14A and 14B include graphs 1400A and 1400B of thrust, thrust-to-power ratio, specific impulse, and anode efficiency all plotted as functions of discharge voltage at four different sidewall electrode voltages for a Hall effect thruster using one embodiment of magnetically-shielded sidewall electrodes. The data is measured over a discharge voltage range of 125-250 V at a discharge current of 9 A with krypton as the propellant. The thruster does not operate stably at a discharge voltage of 100 V on krypton and, thus, this operating condition is not included. The mass flow is held constant for all voltage settings. The setup allows the discharge current to change freely when changing electrode voltage. This generally results in an increase in discharge current with electrode voltage. The calculations of T/P ratio and anode efficiency include the additional power required for the electrodes. For clarity, error bars for T/P ratio, Iₛₚ, and anode efficiency are omitted from the figures.

FIGS. 14A and 14B show an increase in thrust as the electrode voltage increases. The increase is larger at lower discharge voltages. The T/P ratio however shows a continual decrease with applied electrode power. The increase in thrust is offset by the additional electrode power, and results in lower T/P ratio than in the case without electrodes. If electrode power is not considered, the T/P ratio increases with applied electrodes. The Iₛₚ and anode efficiency both show increases at low voltages and decreases or no change at higher voltages. The switch over point from improvement to no improvement with respect to I_{SP} and efficiency is around 175 V discharge for the particular embodiment under test.

### Thick Electrodes

After the thin electrodes suffered significant damage due to high Ohmic heating when running at 20 A discharge current, a new thicker set was fabricated and tested. The new 0.05 in. thick electrodes are incorporated to withstand the thermal load generated by biasing the electrodes. The thruster is again tested at 9 A over the same range as the thin electrodes, and at 20 A from 125-225 V discharge and 10 V electrode bias.

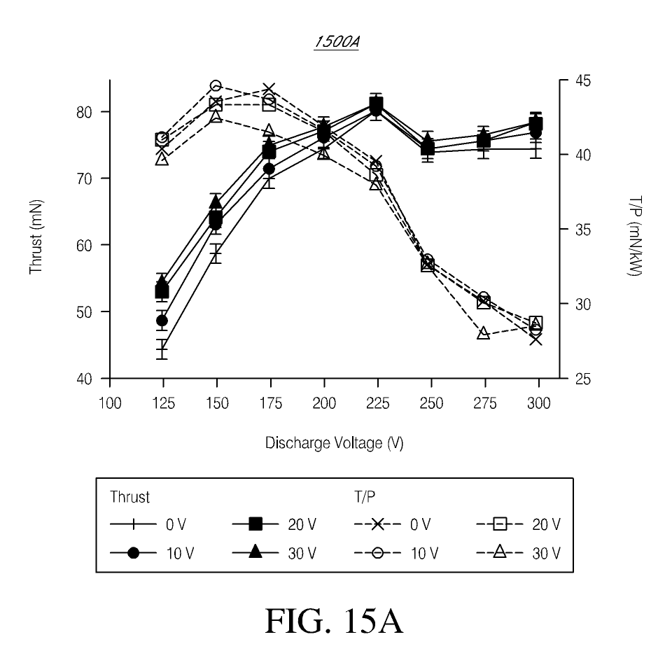

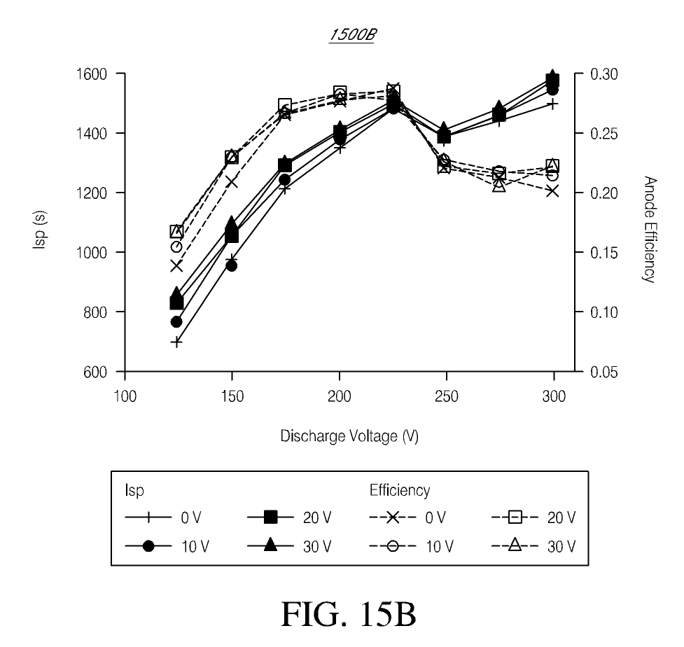

FIGS. 15A and 15B include graphs 1500A and 1500B of thrust, thrust-to-power ratio, specific impulse, and anode efficiency all plotted as functions of discharge voltage at four different sidewall electrode voltages for a Hall effect thruster using another embodiment of magnetically-shielded sidewall electrodes. FIGS. 15A and 15B show the results for the 9 A case. There is a similar increase in thrust at low voltages, but the overall effect is different. Instead of being only effective below 175 V, the electrodes continue to increase thrust up to 225 V. The T/P ratio is also higher with the thick electrodes than thin. The majority of the points still show a decrease in T/P ratio with electrode voltage. However, a few points at 125 and 150 V show an increase. The Iₛₚ and efficiency also increase as the electrode voltage increases, but the increase is not as large compared to the thin electrodes. At 125 V, the small/thin configuration shows a 213 s in Iₛₚ and a 3.5% increase anode efficiency, whereas the small/thick configuration only shows an increase of 157 s in Iₛₚ and 2.8% in anode efficiency. The increases in thrust, Iₛₚ, and efficiency persists until 225 V with thick electrodes as opposed to 175 V with the thin electrodes.

### High Current

The thruster was next run at a higher discharge current of 20 A, to determine if the electrodes have a more significant effect with higher current and the associated increased ion density.

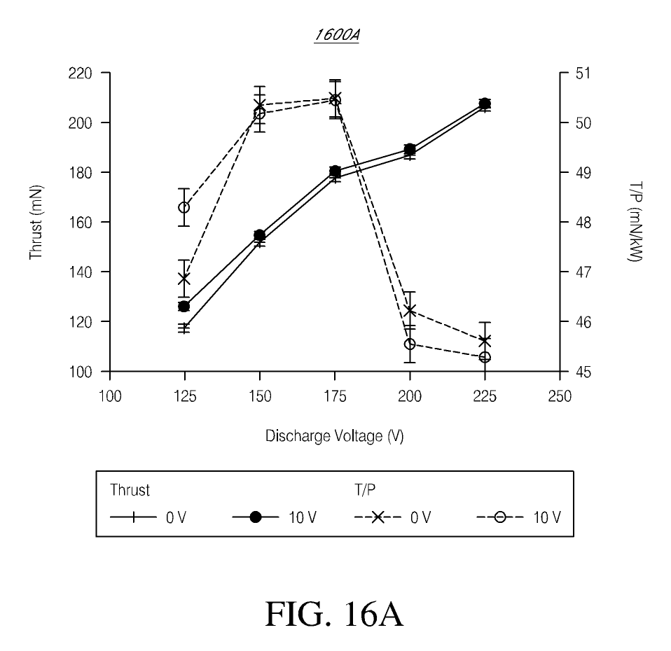

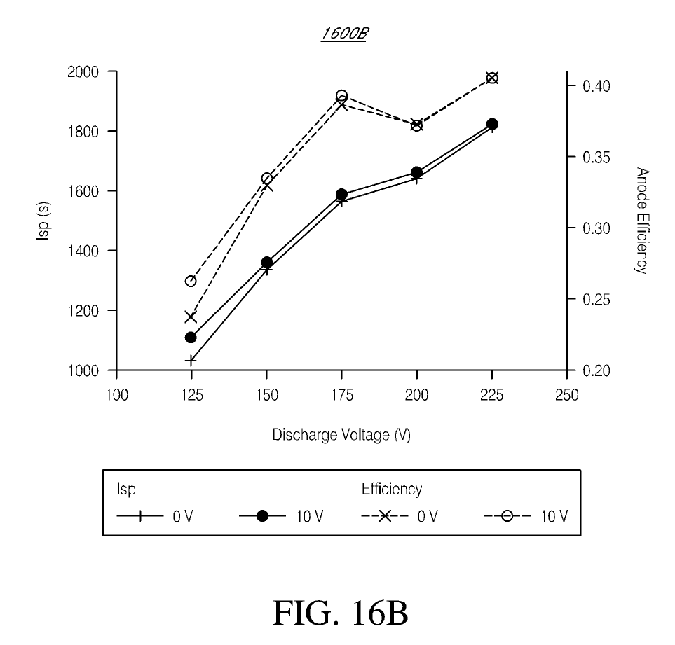

FIGS. 16A and 16B include graphs 1600A and 1600B similar to those shown in FIGS. 15A and 15B, except that the Hall effect thruster was operated at a higher discharge current. FIG. 16 shows the performance at a discharge current of 20 A. The thrust, T/P ratio, Iₛₚ, and efficiency improvement with the electrodes is higher for 20 A than for 9 A. This seems to confirm the idea that biased electrodes generate larger performance improvements at higher discharge currents. The larger number of ions generated at high currents means more ions are repelled from the wall and focused toward the centerline of the discharge channel, thus generating more thrust.

### Xenon Performance

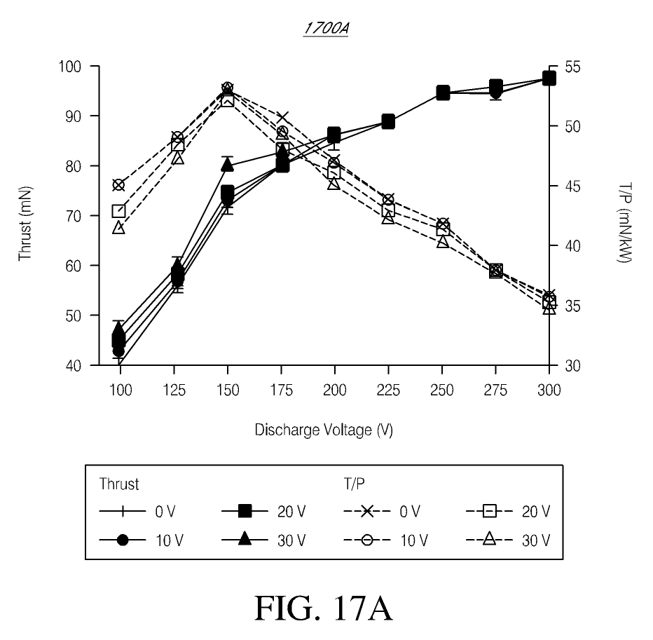

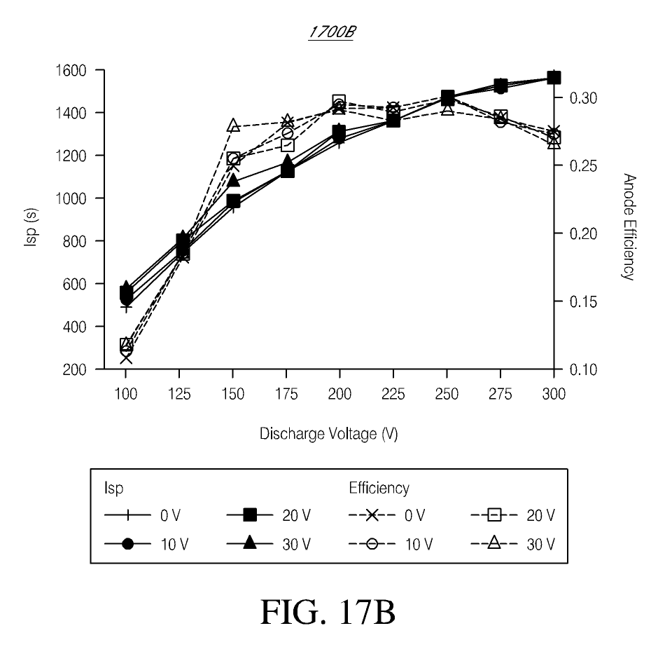

The final data taken were with respect to the xenon tests. FIGS. 17A and 17B include graphs 1700A and 1700B similar to those shown in FIG. 15, except that xenon was used as the propellant for the Hall effect thruster instead of krypton. Xenon was, at the time, rather expensive. Thus, a small sample of data was taken, as shown in FIGS. 17A and 17B at 9 A current. The xenon electrode performance is higher than krypton in all four metrics, as expected. Xenon has an overall better performance than krypton due to its lower ionization cost and increased mass. With the sidewall electrodes, however, the increases in thrust, Iₛₚ, and efficiency with electrodes are lower for xenon than krypton. The reason for this is not known, and difficult to speculate with limited data.

### Discussion

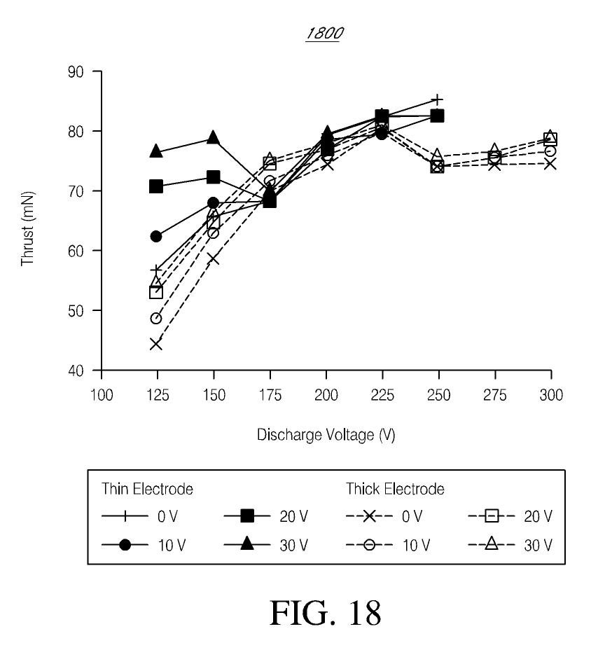

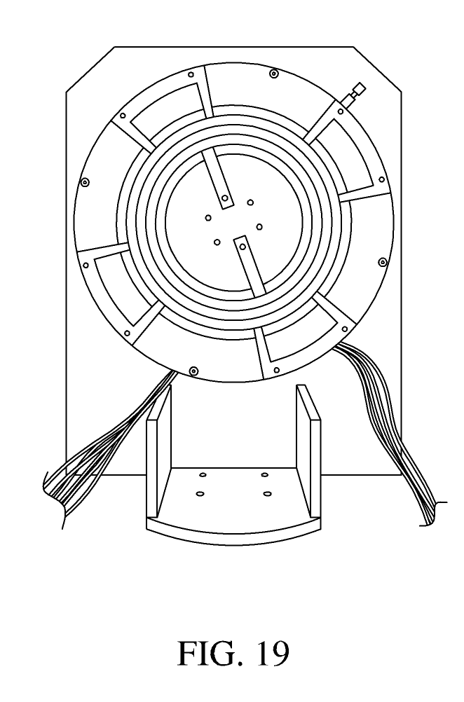

The addition of sidewall electrodes, as discussed herein, definitely has a positive effect on the thruster performance, increasing thrust, Iₛₚ, and efficiency consistently at certain voltage ranges. The effect on the T/P ratio is more variable, but does show signs of improvement due to the electrodes. Even with increasing thrust, the additional power on the electrodes causes a detrimental factor on the T/P ratio. Decreasing the electron current to the electrodes will increase T/P. This can be accomplished by better magnetic shielding, or decreased physical presence in the plasma. FIG. 18 is a graph 1800 of thrust plotted as a function of discharge voltage at four different sidewall electrode voltages in a Hall effect thruster using the two different embodiments of magnetically-shielded sidewall electrodes. The physical presence of the electrodes in the plasma has a noticeable effect on the thruster, as can be seen in FIG. 18, where the thrust for the original thin electrodes (0.015″) and the thick electrodes (0.05″) are plotted.

The thin electrode generates more thrust at the same conditions, and this can be at least partially attributed to the decreased physical interference of the thin electrode. To this end, the next step of this research was to remove the presence of the electrodes by embedding them within the walls of the channel, thus resulting in a flush surface.

### V. Embedded Electrode HET (EEHET)

The initial tests with the thin and thick electrodes prove that the thickness and, thus, the physical presence of the electrodes in the discharge channel has an effect on the thruster performance. Thus, in some embodiments, a smooth channel wall at the interface with the electrodes is provided to improve performance. To that end, a new discharge channel is built with electrodes embedded within the channel wall itself. The embedded electrode Hall effect thruster (EEHET) is retested at the same conditions to allow side by side comparisons. The channel is the exact same design, but a portion of the walls will be removed to allow the addition of electrode rings.

The discharge channel is a new fabrication, made with embedded electrodes in mind. The channel conforms to the original thruster drawings, with the addition of cut out grooves for the electrodes. Two pairs of small holes (0.08 in.) are drilled in the side wall of the channel to feed wires for the electrode connections. The electrodes are made from superfine isomolded graphite. They are 0.4 in. wide and 0.2 in. thick. Graphite is a conductive material that withstands thermal stresses better than steel and has lower Secondary Electron Emissions, which results in a hotter plasma which in turn give better performance. The electrodes have the same connection holes as the channel for wiring. Ceramic rings, of the same material as the channel, are used to make up the extra space in the grooves. This allows for a smooth continuous channel surface. Steel clips have been fabricated to hold the space rings and electrodes in place. The clips are flush with channel and do not protrude into the channel area, thus should not substantially interfere with the thruster operation. The NASA-173M thruster design has some similar characteristics as the EEHET that was built.

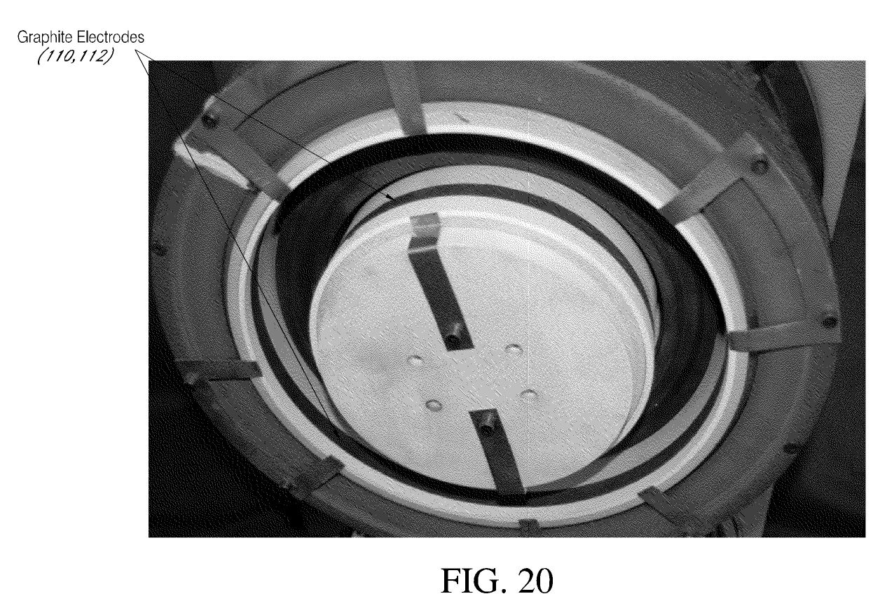

FIG. 19 is an illustration of a Hall effect thruster having electrodes embedded within the inner and outer sidewalls of the discharge channel. FIG. 20 is a close-up photograph of a Hall effect thruster similar to the one illustrated in FIG. 19, which better illustrates the electrodes embedded within the inner and outer sidewalls of the discharge channel. FIG. 20 shows the new channel with graphite electrodes and ceramic spacer rings. The embedded nature of the electrodes should allow for improved performance, and easier diagnostics of the plasma sheath around the electrode and cusp fields.

### VI. EEHET Plasma Diagnostics

### Vacuum Facility

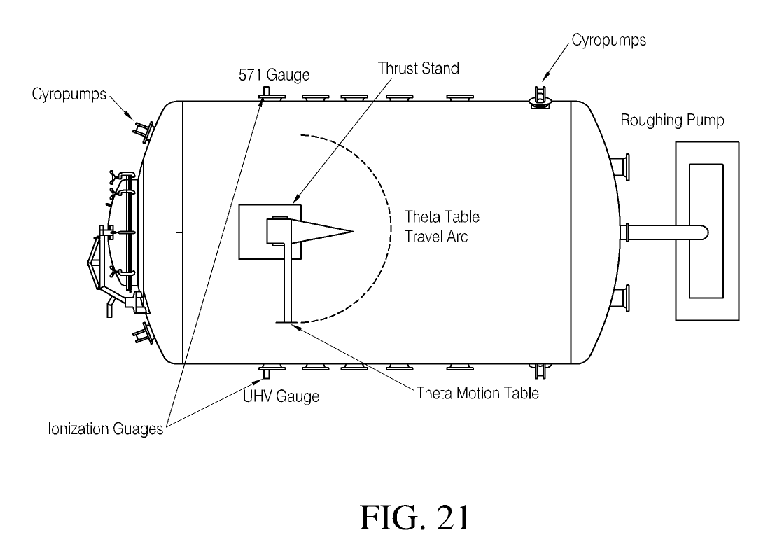

The EEHET is tested in a larger vacuum chamber than used for the previous designs. The system is a cryopumped chamber 9.2 meters long and 4.9 meters in diameter. It is pumped to rough vacuum with one 3800 CFM blower and one 495 CFM rotary-vane pump. Ten liquid nitrogen cooled CVI TMI re-entrant cryopumps with a combined pumping speed of 350,000 l/s on xenon bring the chamber to a base pressure of 1.9×10⁻⁹ Torr. The system also incorporates a liquid nitrogen regeneration system to reduce operating costs. The regenerator is a Stirling Cryogenics SPC-8 RL Special Closed-Looped Nitrogen Liquefaction System with a reservoir capacity of 1500 liters of LN₂. FIG. 21 shows a schematic of the cryopumped vacuum facility.

### Thrust Stand

An identical thrust stand to that used in the previous design is installed in the cryo vacuum chamber and used for all performance testing of the EEHET.

### High-Speed Axial Reciprocating Probe

A High-Speed Axial Reciprocating probe (HARP) is a high speed linear actuator capable of 3 m/s speeds and minimum residence times up to ˜50 ms at the target location. The HARP is used to interrogate the discharge channel plasma in conjunction with a miniature emissive probe. Taking measurements inside a discharge channel of a HET is very difficult due to the energetic nature of the hot plasma. Energetic particles will strike and damage probes placed in the plasma in quick order. Previous calculations for an alumina probe in the discharge plasma show a minimum probe ablation time of 150 ms. The HARP allows probes to be used in the channel without damage.

### Faraday Probe

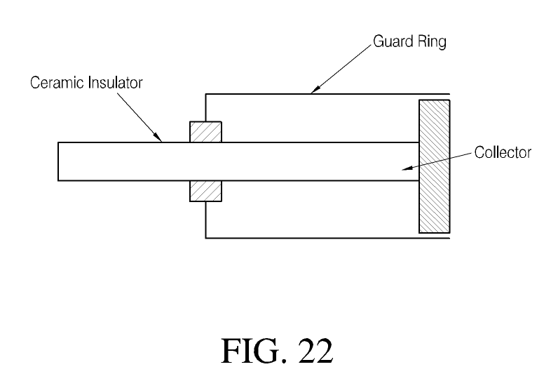

A Faraday probe is used to measure the exhaust plume ion current density by collecting ions that strike the collector face. FIG. 21 is a schematic representation of a Faraday probe that can be used to measure ion density in the plume of a Hall effect thruster. FIG. 22 is a photograph of the Faraday probe of FIG. 21. The Faraday probe is placed in the plume of the thruster and measures the collected ion current. With knowledge of the collected ion current, the ion density can be found. By sweeping the probe in a 180 degree arc around the thruster at different electrode operating conditions, the total ion density or ion number can be found. If the electrodes are reducing wall neutralization, then the ion density will be higher with sidewall electrodes compared to without.

### Retarding Potential Analyzer

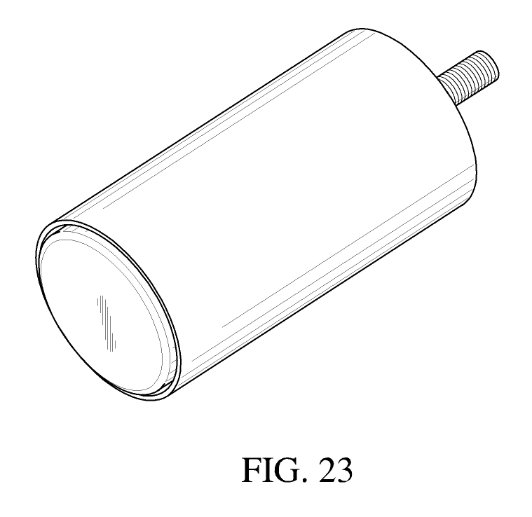

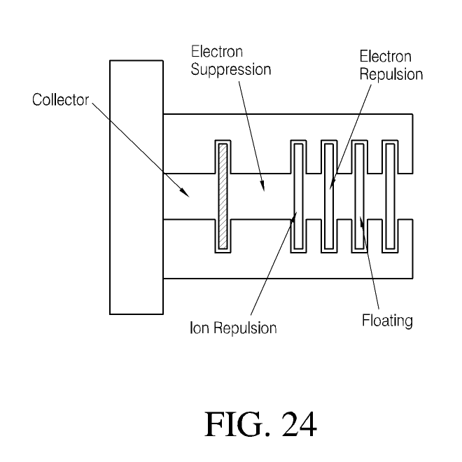

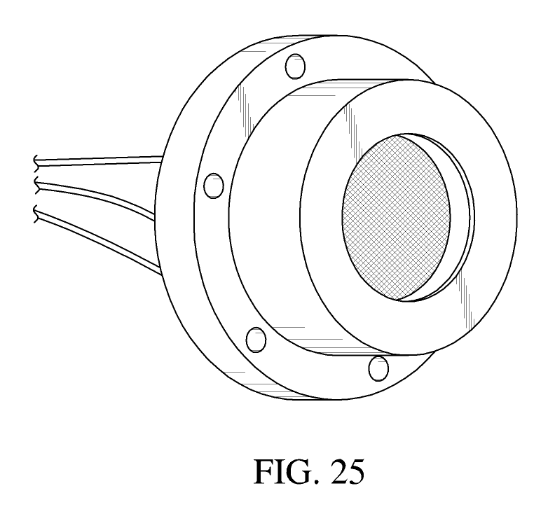

A second probe, the Retarding Potential Analyzer (RPA), is used to measure the ion energies in the plume. FIG. 23 is a schematic representation of a Retarding Potential Analyzer that can be used to measure ion energies in the plume of a Hall effect thruster. FIG. 24 is a photograph of the Retarding Potential Analyzer of FIG. 23. The probe consists of a set of biased grids used to repel electrons and select ions based on their energy/velocity. The selected ions hit a collector and generate current. By varying the selection voltage, the ion energy distribution and average ion energy can be determined.

By sweeping the RPA in the same manner as the Faraday probe, we can determine the change in ion energies with the electrodes. As stated before, the repelling function of the electrodes should reduce radial ion energies and contribute to increased axial energy. By knowing the angle of the measurement, the ion current density from the Faraday probe, and the ion energy at that angle, the change in axial and radial ion energies due to the electrodes can be determined. This allows us to know which effect, the ion-wall repulsion or the beam collimation, has a greater effect, and will lead to better designs.

### Floating Emissive Probe

A floating emissive probe is used to measure the plasma potential inside the discharge channel. The emissive probe is a half circle loop of wire held in an insulator. Current passed through the wire causes thermionic emission of electrons. The emitted electrons neutralize the surround sheath and allow the probe to float to the local potential. The emissive probe along with the HARP allows mapping of the in-channel potential fields. Electric field lines run normal to potential contours, thus the probe can show the electric fields caused by the electrodes.

### VII. EEHET Performance

### Krypton Performance

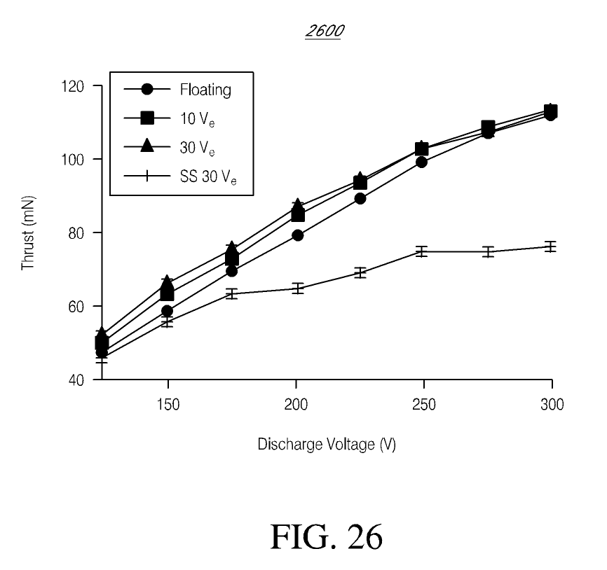

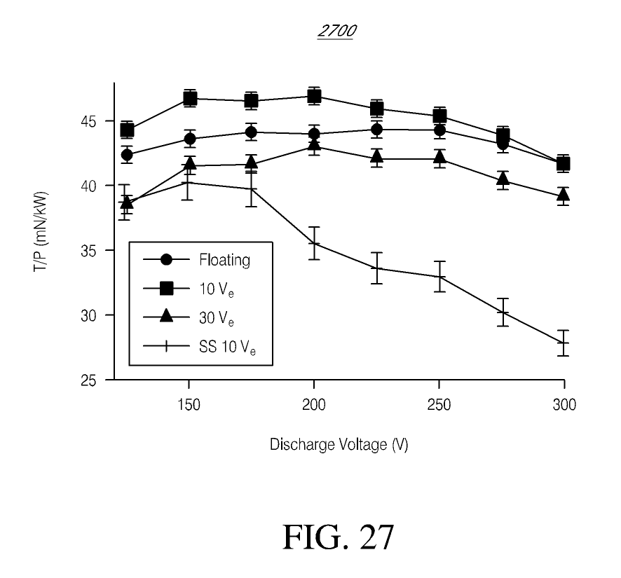

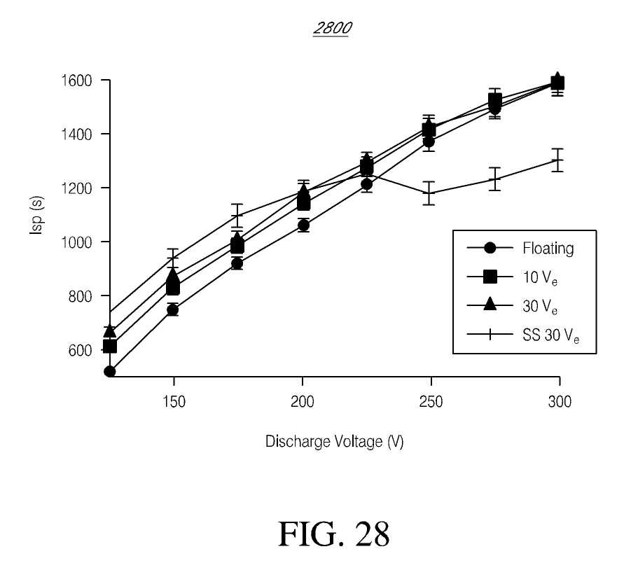

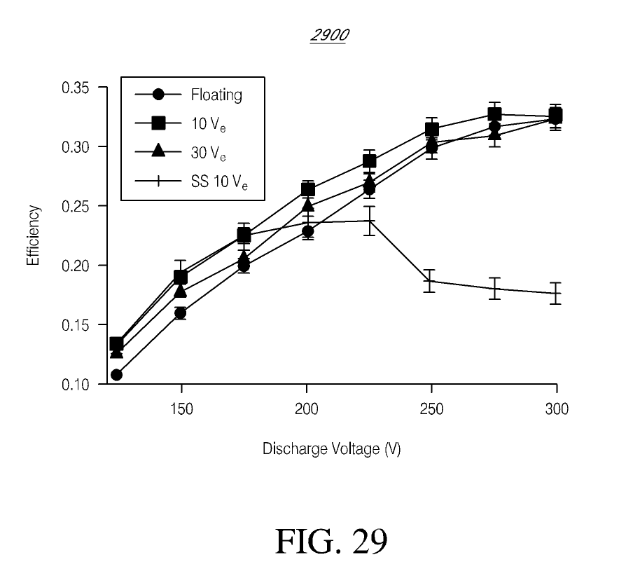

The thruster is first tested with krypton propellant from 125-300 V at 9 A discharge and three sidewall electrode conditions of floating, 10 Vₑ and 30 Vₑ where the “e” subscript denotes electrode voltage above anode. The floating condition has the electrode disconnected electrically. This allows comparison to the previous designs with stainless steel electrodes. FIGS. 26-29 show performance results of the EEHET on krypton.

FIGS. 26-29 are graphs of thrust, thrust-to-power, specific impulse, and efficiency plotted as a function of discharge voltage in an embedded electrode Hall effect thruster with krypton propellant for various sidewall electrode voltages. Data from the best performance cases from the thick stainless steel (SS) electrode are also included for comparison. The embedded electrode shows higher thrust and T/P ratio compared to the stainless steel electrodes. The specific impulse and efficiency are lower at low voltages. This can be attributed to the higher mass flow necessary for the EEHET to maintain the same discharge conditions. The two different vacuum chambers have different pumping rates and pressure. The cryo chamber has a much lower pressure, thus less ingesting of chamber neutrals which can inflate the current. This requires more propellant to meet the same current. As both specific impulse and efficiency include the mass flow rate in their calculations, this would make the EEHET numbers smaller.

The EEHET shows clear changes with electrodes biased to 10 Vₑ and 30 Vₑ. Similar to the stainless steel electrodes, the higher electrode bias causes a decrease in T/P ratio due to increased current collection.

### Xenon Performance

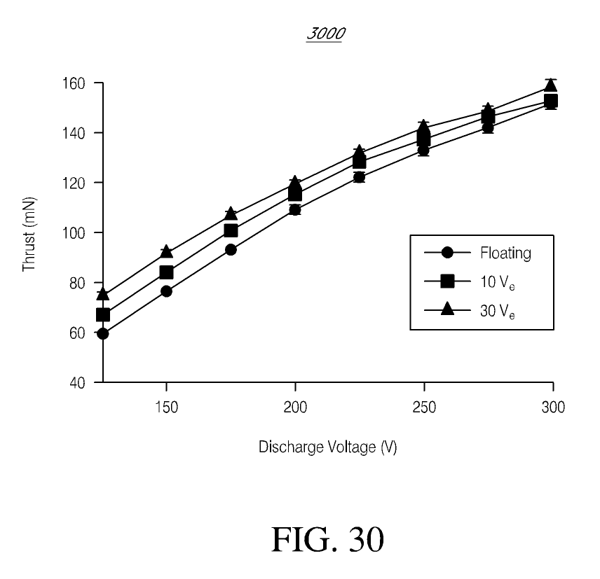

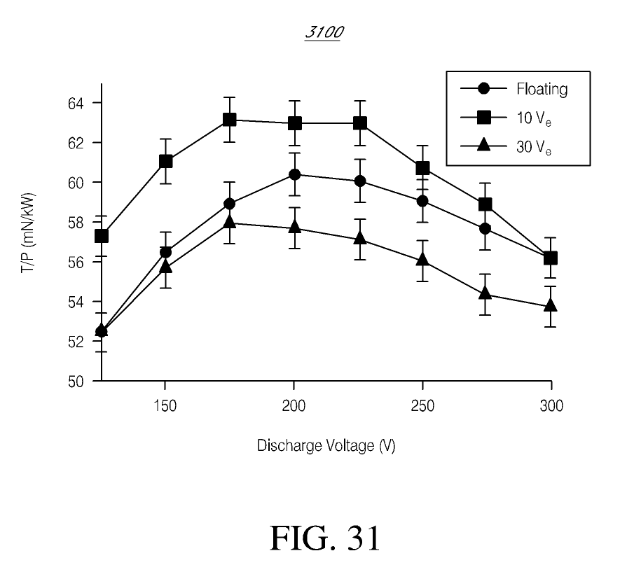

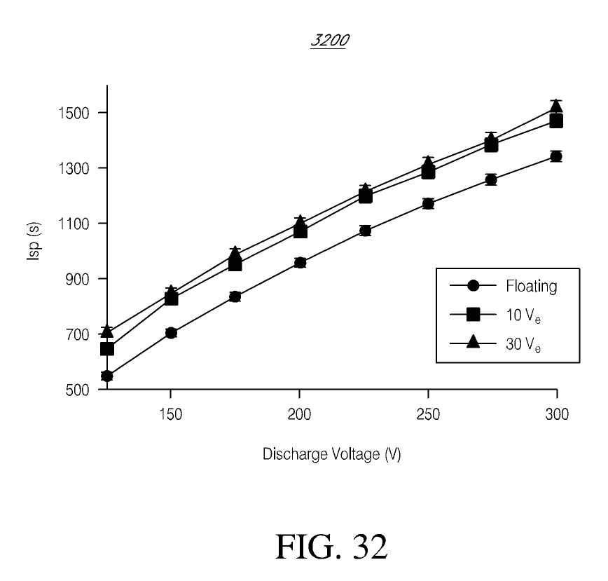

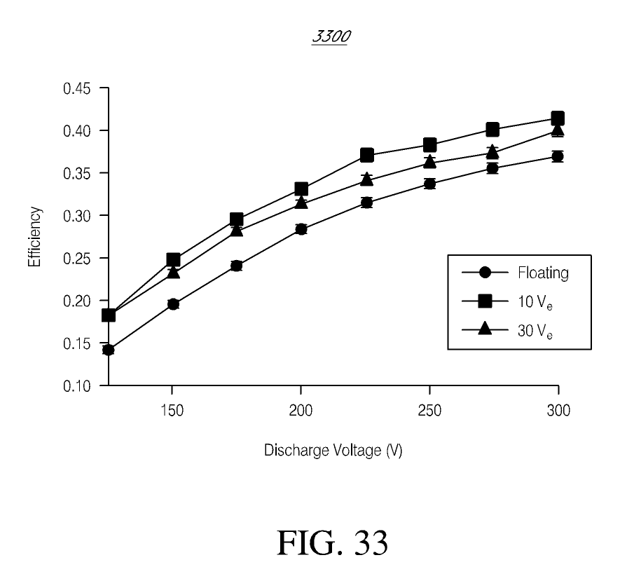

The thruster is tested on xenon propellant next. The same test conditions, namely 125-300 V at 9 A and three electrode conditions of floating, 10 Vₑ and 30 Vₑ, are tested. FIGS. 30-33 show the performance results for xenon.

FIGS. 30-33 are graphs of thrust, thrust-to-power, specific impulse, and efficiency plotted as a function of discharge voltage in an embedded electrode Hall effect thruster with xenon propellant for various sidewall electrode voltages. The values are generally higher for xenon than krypton due to xenon's larger mass and lower ionization cost which results in more ions and more thrust for the same settings. The improvements due to the electrodes are noticeable. The maximum T/P ratio increase occurs at 150 V anode and 10 Vₑ, resulting in a gain of 7.69 mN (10%) of thrust, 4.6 mN/kW (8.1%) thrust-to-power, 123 s (17.4%) ISP, and 5.3% (27%) anode efficiency. The percent values in the parenthesis indicate percent improvement over the Floating 150 V anode condition. The largest thrust increase is 15.3 mN at 150 V and 30 Vₑ. However the T/P ratio decreased at this condition due to high electrode current.

### Ion Current Density and Plume Divergence

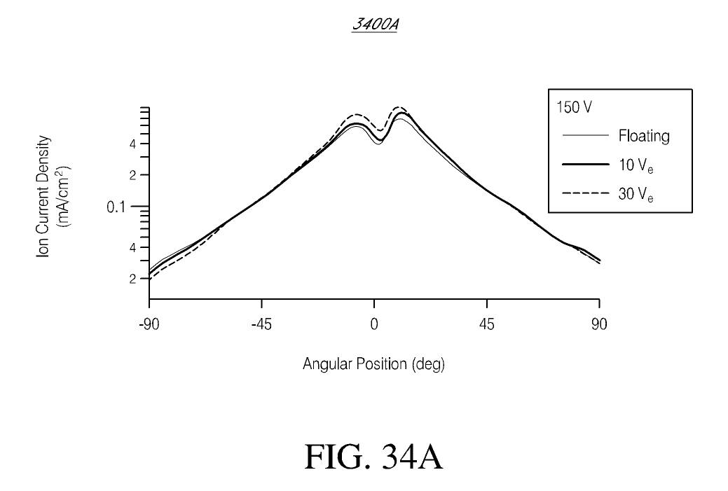

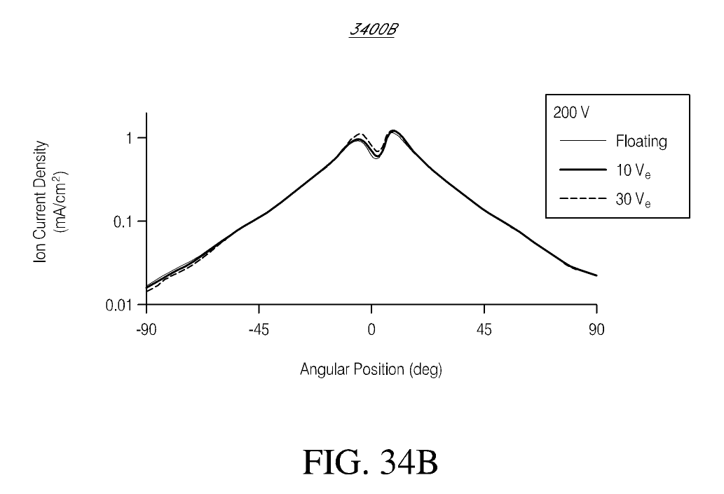

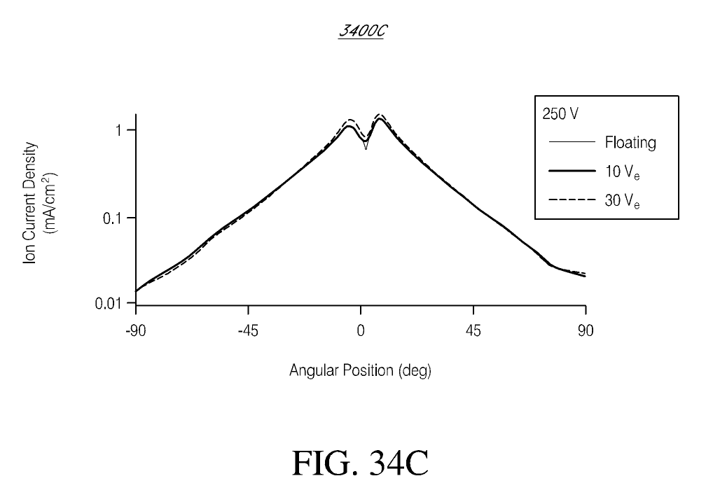

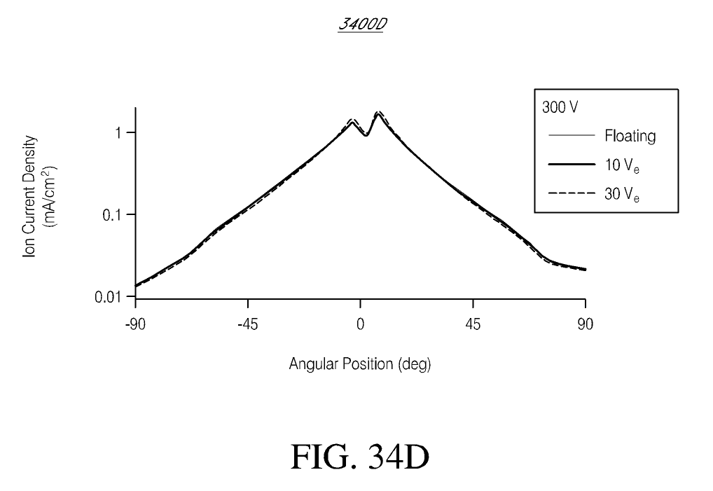

The plume ion current density is measured with the Faraday probe at a constant radius of 1 m. The probe is swept for −90 to 90 degrees from thruster centerline. FIGS. 34A-D are graphs of ion current density plotted as a function of angular position for an embedded electrode Hall effect thruster operating with different discharge voltages and using various sidewall electrode voltages. FIGS. 34A-D show the resultant current profiles for four anode voltages (150V, 200V, 250V, and 300V). With biased electrodes, the profile shows increased density near centerline, and decreased density at large angles.

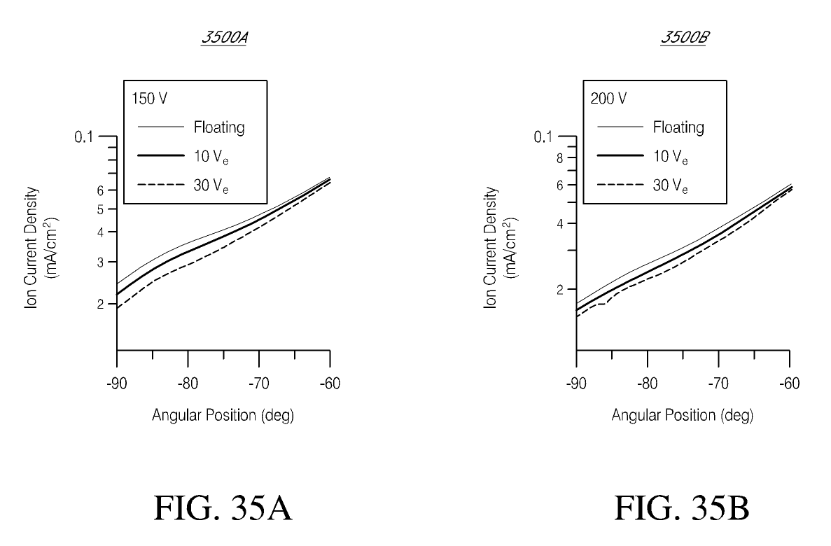

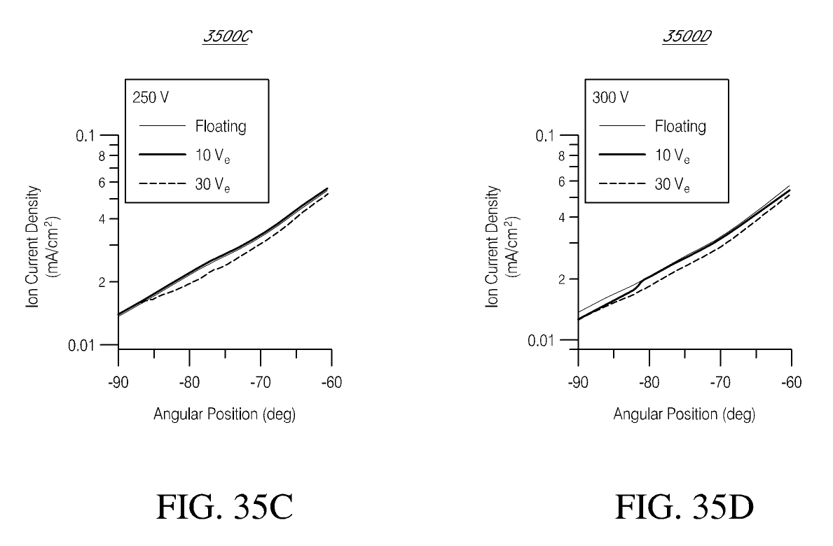

FIGS. 35A-D are graphs that show magnified views of portions of the graphs shown in FIGS. 34A-D. In particular, FIGS. 35A-D show magnified views of the left side of the profiles of FIGS. 34A-D. The drop in density is more clearly seen here. The changes are most pronounced at low discharge voltages.

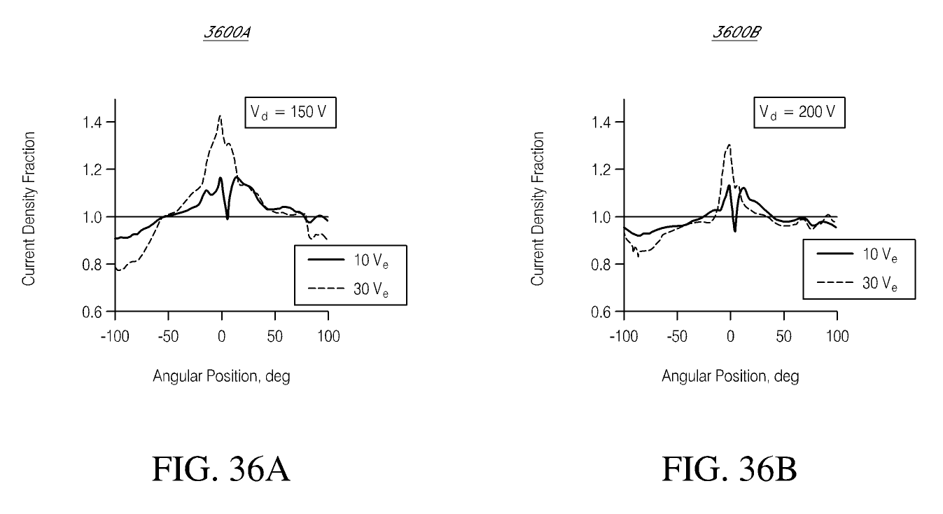

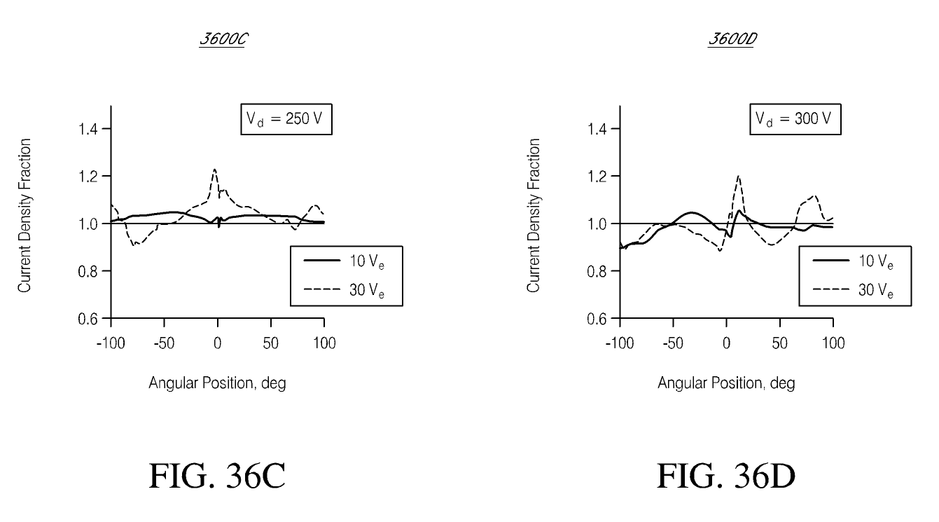

FIGS. 36A-D are graphs of the normalized current densities shown in FIGS. 34A-D. In particular, FIGS. 36A-D show the current density profiles normalized by the floating profile. This shows more clearly the relative change in current densities at small and large angles. The results show ion focusing by indicating that ions are moved from large angles toward small angles. If it was the case of a net increase in number of ions, then the profile would shift vertically instead of narrowing.

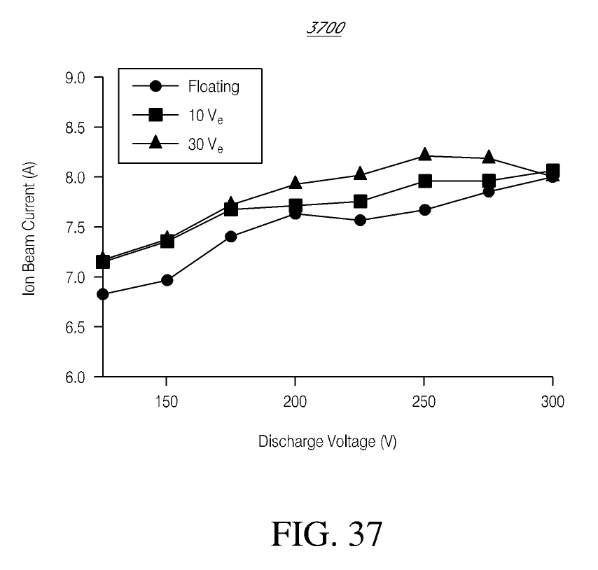

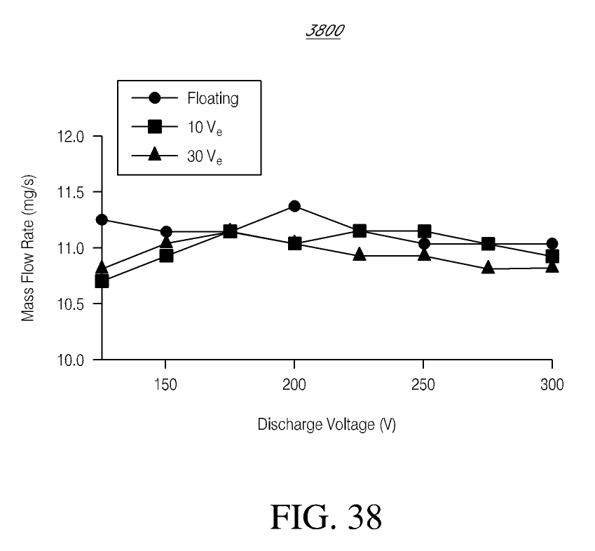

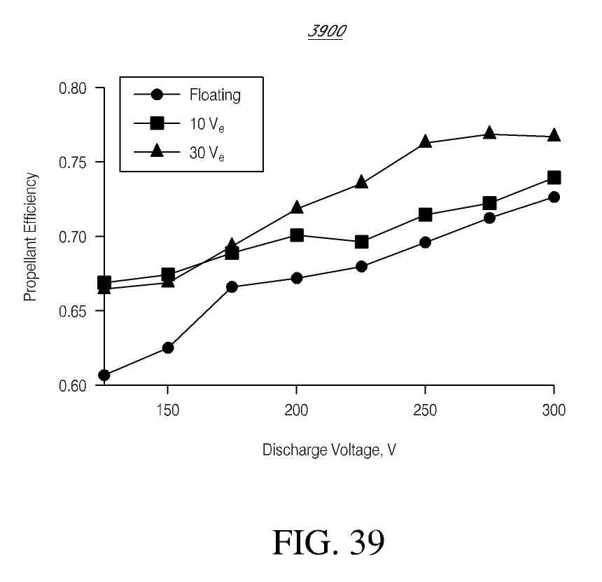

FIG. 37 is a graph of ion beam current plotted as a function of discharge voltage in an embedded electrode Hall effect thruster for various sidewall electrode voltages. FIG. 37 shows the integrated ion beam from the current density profiles. The sidewall electrodes increase the ion beam, which confirms reduction of ion neutralizations. The reduction of neutralization is even clearer when one looks at the mass flow rate and propellant efficiency in FIGS. 38 and 39.

FIG. 38 is a graph of propellant mass flow rate plotted as a function of discharge voltage in an embedded electrode Hall effect thruster for various sidewall electrode voltages. The mass flow rate decreases with biased electrodes, which indicates fewer neutrals are available. However even with fewer neutrals, the ion beam current increases. This can be captured by the propellant efficiency.

FIG. 39 is a graph of propellant efficiency plotted as a function of discharge voltage in an embedded electrode Hall effect thruster for various sidewall electrode voltages. Propellant efficiency may be understood as the ion beam current divided by the mass flow rate. This essentially normalizes each electrode condition to a per propellant mass standpoint. The propellant efficiency shows large increases with biased electrodes, indicating that more ions are exiting the thruster.

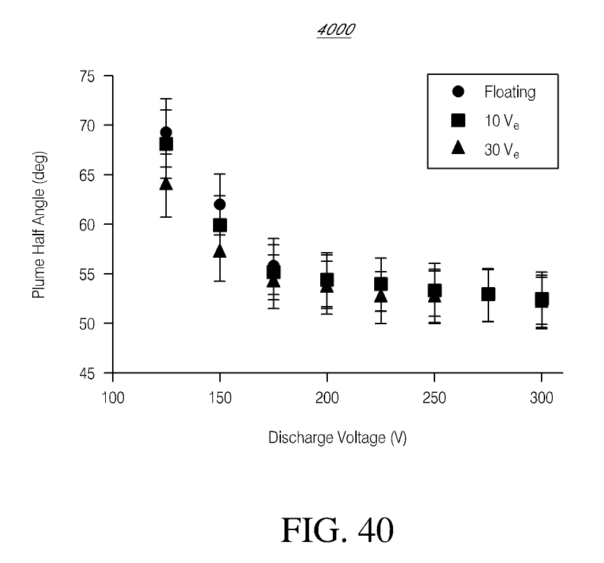

FIG. 40 is a graph of plume half angle plotted as a function of discharge voltage in an embedded electrode Hall effect thruster for various sidewall electrode voltages. FIG. 40 shows the plume divergence angle. The sidewall electrodes decrease the plume divergence angle at low voltages.

### Ion Energy

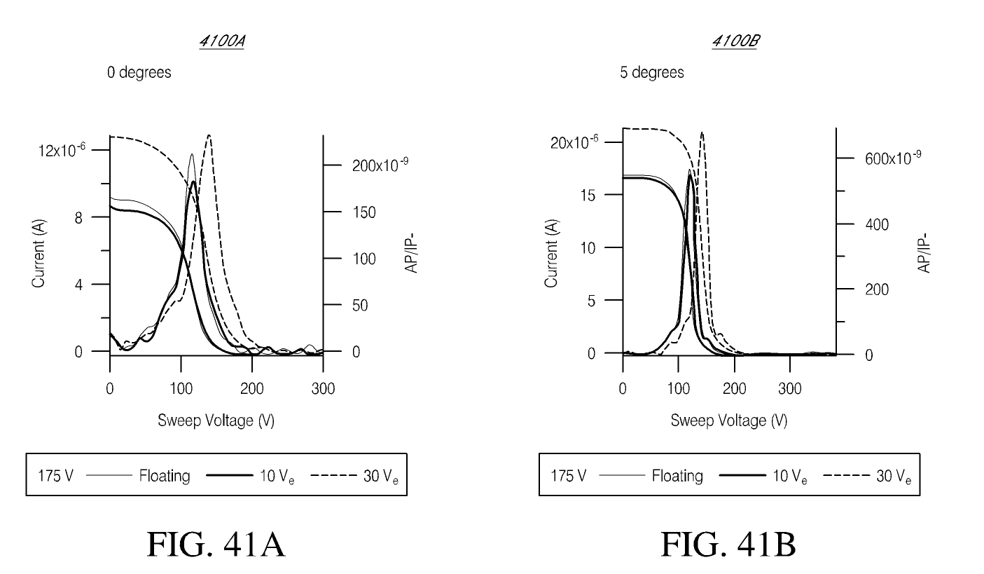

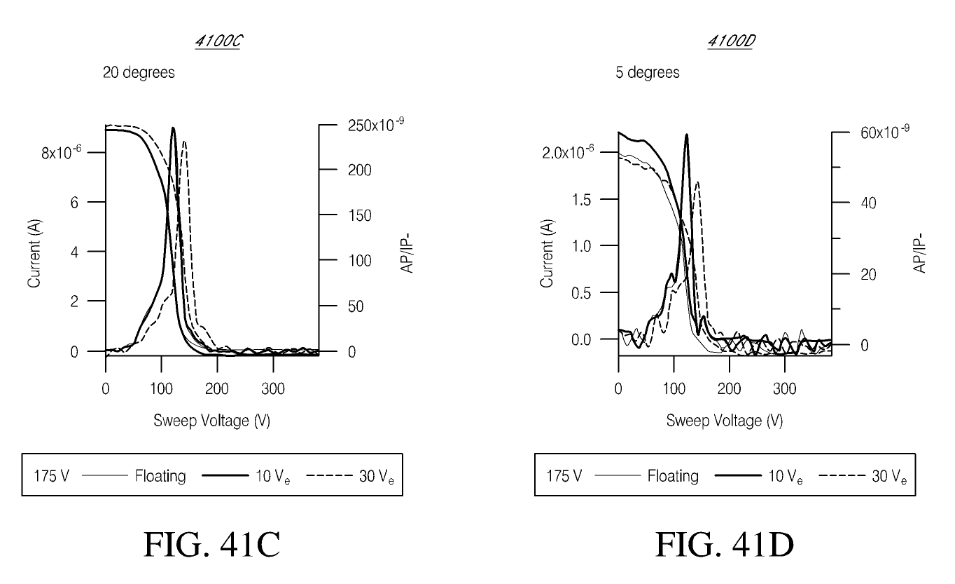

FIGS. 41A-D are graphs of ion energy distribution and current plotted as a function of sweep voltage in an embedded electrode Hall effect thruster at different angles and for various sidewall electrode voltages. FIGS. 41A-D show the computed ion energy distribution functions when the thruster is operating at 175 V and 9 A for all three electrode cases at four angular locations. The biased sidewall electrodes generate a shift in ion energy distribution function to higher voltages. Similar trends are observed for other discharge voltages. The case of 175 V, 10 Vₑ causes a slight rightward shift of the ion energy distribution, on the order of a few volts. At 30 Vₑ, the shift is an average of 20 V.

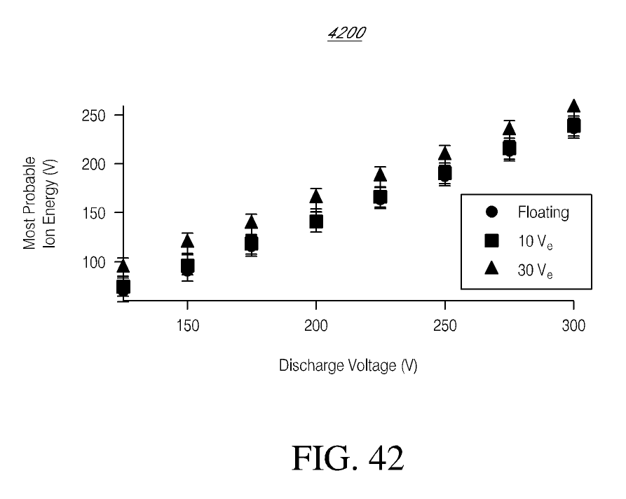

FIG. 42 is a graph of ion energy plotted as a function of discharge voltage in an embedded electrode Hall effect thruster for various sidewall electrode voltages. FIG. 42 shows the centerline ion energy for all the operating conditions. The same trend in ion energy is observed at all discharge voltage levels.

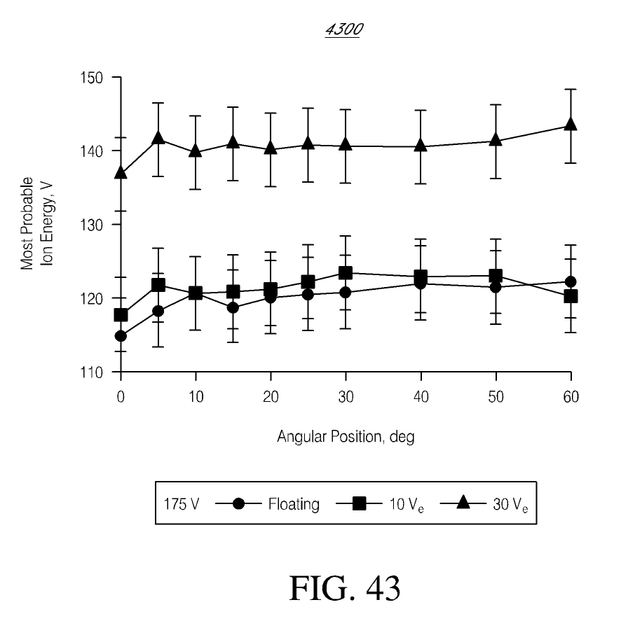

FIG. 43 is a graph of ion energy plotted as a function of angular position in an embedded electrode Hall effect thruster for various sidewall electrode voltages. FIG. 43 plots the most probable ion energy for the 175 V operating condition at all measured angles from 0 to 60 degrees. The electrodes behave differently at 10 Vₑ and 30 Vₑ, which is evident in the different ion energies.

### In-Channel Plasma Potential

In-channel plasma potential measurements are made using the HARP. The thruster is tested at the same three sidewall electrode conditions: floating, 10 Vₑ, and 30 Vₑ. The measurement area is a 26×50 mm area within the channel. A centerline sweep is also taken that extended into the plume.

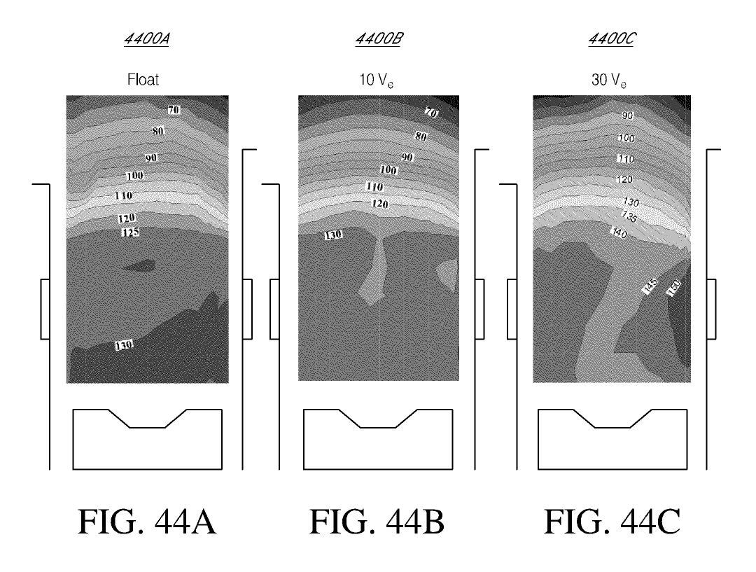

FIGS. 44A-C are illustrations showing electric potential contour lines in an embedded electrode Hall effect thruster for various sidewall electrode voltages. FIGS. 44A-C show the internal plasma potential results for the three conditions. The floating condition shows a potential distribution with a high gradient near the channel exit that defines the ionization/acceleration region. The contours are convex and create a slight diverging electric field near the exit. The diverging electric field will give ions increased radial velocities and cause increased plume divergence angle. Near the anode and electrodes, the potential is relatively flat and surrounds the anode. The potential ranges from 65 to 130 V.

With powered electrodes, there are two main changes to the potential contours. The first is a division of the high potential regions at the upstream end of the channel near the electrodes. It can be seen clearly at 30 Vₑ, and somewhat at 10 Vₑ, that the high potential region near the anode and electrodes split into two separate areas with a lower potential area between.

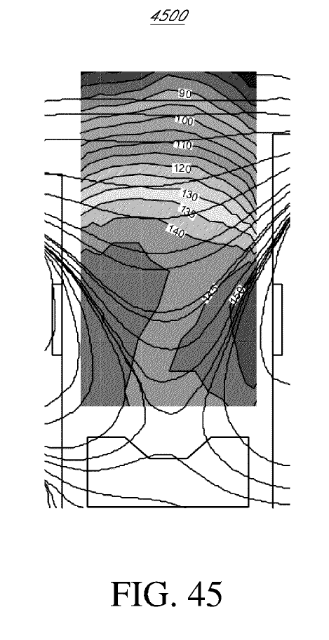

The pockets of high potential conform to the cusp-shaped magnetic field regions to a first order as shown in FIG. 45. This pocketing of the potential will generate electric fields in the back of the channel pointed toward channel centerline. These fields in turn focus ions, and are a possible cause of the observed focusing in the plume data.

The second main change that can be seen in the potential measurements of FIGS. 44A-C is the increase in potential range. When discharge voltage is increased, the potential contours typically experience a similar increase in maximum potential. This is true in the 30 Vₑ case, but not as much at 10 Vₑ. At 10 Vₑ, the maximum potential increased by less than two volts over the floating case. The high potential region is expanded to cover a larger area though. At 30 Vₑ, the maximum potential increased by 24 V over the floating case. This difference in potential increase matches the different ion energy gains seen in the RPA data. The maximum potential may tend to become dictated by the electrodes instead of the anode. This further establishes the notion that at 30 Vₑ the electrodes become the primary positive electrical terminal instead of the anode.

### Thruster Acceleration Region

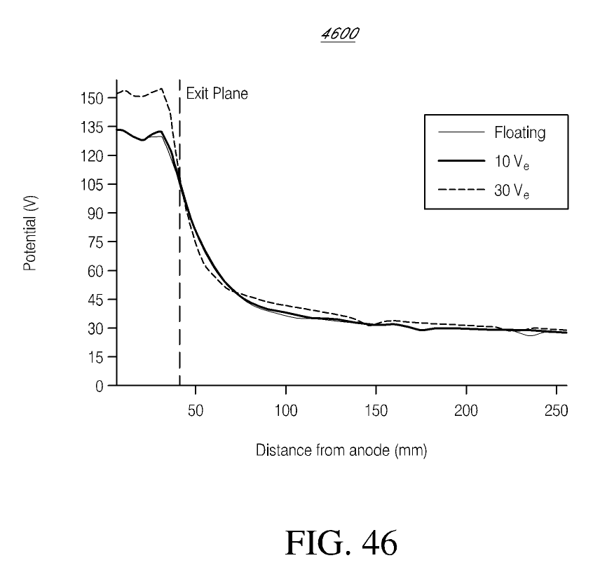

The increased potential range within the discharge channel is largely due to increase maximum potential. At the downstream end of the measured region, the minimum potential is relatively constant around 70 V. Likewise in the far-field the plasma potential is very similar between the three electrode conditions as can be seen in FIG. 46.

FIG. 46 is a graph of electric potential plotted as a function of distance from the anode in an embedded electrode Hall effect thruster for various sidewall electrode voltages. The maximum far-field potential increase is 0.78 V from floating to 30 Vₑ. This increased maximum potential without a similar increase in minimum potential results in an increased potential drop magnitude and slope. FIG. 46 shows the centerline plasma potential measured with the miniature emissive probe from the near anode region to multiple channel lengths downstream. The floating and 10 Vₑ cases have nearly identical potential profiles while the 30 Vₑ profile shows the increased maximum potential, but similar far-field potential.

One effect of the sharper potential drop at 30 Vₑ is a shorter acceleration region. The acceleration region is the axial length where the majority of the potential drop occurs and ions are accelerated by the electric field. The acceleration region can be quantified by plasma potential or electric field.

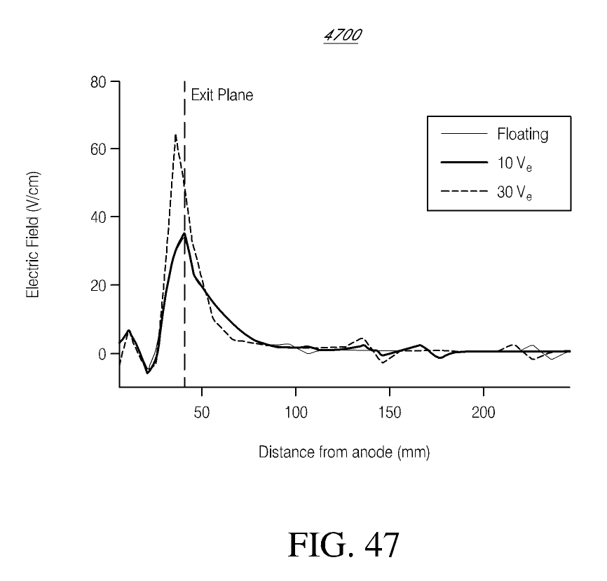

FIG. 47 is a graph of the electric field strength plotted as a function of distance from the anode in an embedded electrode Hall effect thruster for various sidewall electrode voltages. Looking at centerline plasma potential shown in FIG. 46, the acceleration region can be taken to be between 90% and 10% of the total potential drop. Looking at electric field shown in FIG. 47, which is simply the derivative of the potential in FIG. 46, the acceleration region can be taken as the region between 0.15 Eₘₐₓ.

The acceleration region length calculated with the two methods is shown in Table 2. Both methods largely agree on the start and end of the acceleration regions for the floating and 10 Vₑ cases. The electric field method gives a longer acceleration region. At 30 Vₑ though, the two methods give very different values for the acceleration length. The electric field predicts a much shorter acceleration region. This is due to the high maximum electric field at 30 Vₑ which causes the 0.15 E. value to be larger and results in a smaller range. If we instead use the 0.15 Eₘₐₓ value for 10 Vₑ, the resulting length of 41 mm is much more comparable to the potential calculated length of 44.46 mm.

TABLE 2

| | Floating | 10 Vₑ | 30 Vₑ |
|---|---|---|---|
| Potential | | | |
| Accel Start (mm) | 34.01 | 35.87 | 36.38 |
| Accel End (mm) | 82.59 | 83.83 | 80.84 |
| Accel Length (mm) | 48.59 | 47.96 | 44.46 |
| Electric Field | | | |
| Accel Start (mm) | 32.03 | 32.81 | 33.37 |
| Accel End (mm) | 84.30 | 83.78 | 66.17 |
| Accel Length (mm) | 52.26 | 50.98 | 32.80 |

Whichever method is used, the acceleration region shrinks with increased electrode potential. In theory the length of the acceleration region should not affect the ion acceleration mechanism. However in reality there are a number of factors that can interfere with ion acceleration. The downstream potential contours are the same for all three cases, thus the electric fields are similar. The electric fields diverge downstream of the channel exit, and can cause plume divergence. A long acceleration region will cause more divergence as ions follow the electric field further out and gain more radial energy. A long acceleration region also increases the chances of ion collisions with other particles that can cause charge exchange or neutralization. Overall, a shorter acceleration region results in better performance.

The start of the acceleration region also moves downstream with the use of the sidewall electrodes. Movement of the acceleration region is primarily of interest for plume angle and channel erosion. As the acceleration region is shifted upstream toward the anode, the apparent exit angle for ions decreases. Ions that would have large radial vectors exiting the channel are now neutralized as they impact the channel. This may contribute to the reduced plume angle, but doesn't explain the other observed changes such as increase ion density. The location of the acceleration region also effects channel erosion for the same reasons. A smaller exit angle causes increased ion flux to the channel walls and increases the erosion rate. An acceleration region farther downstream would have reduced erosion, but higher plume divergence. In this work, the upstream shift of the region start may contribute to the reduced plume angle seen in the Faraday probe data.

The electrodes may also be causing a TAL like behavior in the thruster. In TAL thrusters, the channel walls are made of conductive metal and the anode is very close to the channel exit. The acceleration region sits close to the anode, thus the name “thruster with anode layer.” In the EEHET, the acceleration region is moving closer to the electrodes and away from the anode. The acceleration region start moves downstream, while the region end moves upstream. This compresses the region and gives support to a more TAL like behavior as TALs generally have thinner acceleration regions with higher electric fields than SPTs.

### Difference Between Electrode Bias Levels

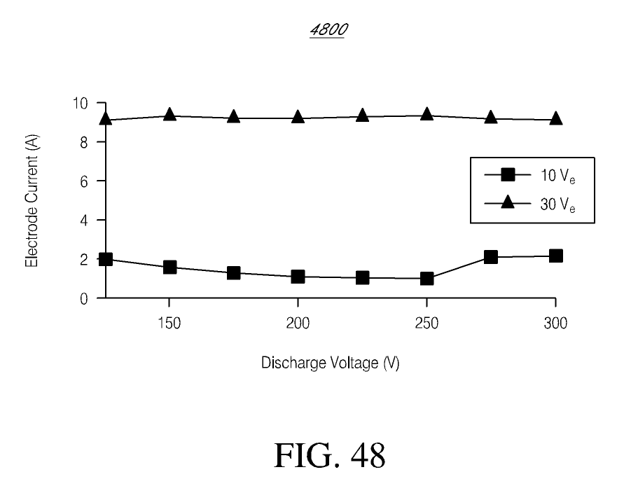

There are significant differences between 10 Vₑ and 30 Vₑ in both performance and plasma measurements. These differences can be attributed to the different level of electron current on the electrodes. FIG. 48 is a graph of electrode current plotted as a function of discharge voltage in an embedded electrode Hall effect thruster for various sidewall electrode voltages. FIG. 48 shows the collected current on the electrodes. At 10 Vₑ the sidewall electrodes saw less than 2 A current. In this case, the sidewall electrodes caused increased current density but little change in ion energy. At 30 Vₑ the electrodes collected almost the entire 9 A of discharge current, leaving less than 1 A on the main anode. This causes higher thrust but increased power consumption. In addition a large increase in ion energy was observed. The results indicate that at 30 Vₑ the electrodes took over for the anode at the main positive terminal. This would explain the increase in electron energy and thrust.

### VIII. CONCLUSION

The Pratt & Whitney T-220HT modifications are designed to increase the T/P ratio of the device. Positively-charged electrodes focus ions into the center of the channel while a ring-cusp magnetic field configuration reduces electron collection by the electrodes. The design changes are made in a way as to leave the integrity of the thruster intact and allow it to be used in its original configuration, without the ring-cusp electromagnets or chamber wall electrodes turned on, with little deviation from previous experimental testing.

The version 2 design showed definite performance improvements, validating the electrode theory. Noticeable increases in thrust, Isp, and efficiency are observed, but the T/P ratio is inconclusive. The T/P ratio is affected by the additional power on the electrodes. This can be reduced by decreasing the electron current the electrodes collect. Data also shows that thinner electrodes give larger performance increases, in some embodiments, due to their small physical presence in the plasma. The embedded electrode HET is designed with these results in mind. By embedding the electrodes in the discharge channel wall, their physical presence in the channel area is removed. With no physical presence, performance increases are greater. The EEHET has larger performance increases than before in all categories of thrust, Isp, efficiency, and T/P ratio. Plume diagnostics show that ion focusing and reduction of neutralization occurs as desired. In-channel plasma potential measurements show the creation of pocketed potential contours which create focusing electric fields.

Embodiments have been described in connection with the accompanying drawings. However, it should be understood that the figures are not drawn to scale. Distances, angles, etc. are merely illustrative and do not necessarily bear an exact relationship to actual dimensions and layout of the devices illustrated. In addition, the foregoing embodiments have been described at a level of detail to allow one of ordinary skill in the art to make and use the devices, systems, etc. described herein. A wide variety of variation is possible. Components, elements, and/or steps may be altered, added, removed, or rearranged.

The foregoing disclosure has partitioned devices and systems into multiple components or modules for ease of explanation. It is to be understood, however, that one or more components or modules may operate as a single unit. Conversely, a single component or module may comprise one or more sub-components or sub-modules.

One or more hardware and/or software controllers can be included for controlling the devices and systems described herein. A hardware controller may be implemented, for example, as a general purpose processor, or as a dedicated processor, such as an Application Specific Integrated Circuit. In the case of a controller that is implemented using software, the software can include one or more modules that include computer-executable code for performing the functions described herein. Such computer-executable code can be stored, for example, in a non-transitory medium, such as computer memory (e.g., ROM or RAM), a hard disk drive, a CD, a DVD, etc.

While certain embodiments have been explicitly described, other embodiments will become apparent to those of ordinary skill in the art based on this disclosure. Therefore, the scope of the invention is intended to be defined by reference to the claims and not simply with regard to the explicitly described embodiments.

What is claimed is:

1. A Hall effect thruster comprising:
an annular discharge channel comprising an inner sidewall radially separated from an outer sidewall;
an anode provided within the annular discharge channel;
an inner sidewall electrode located at an axial position that is downstream from the anode; and
an outer sidewall electrode located at an axial position that is downstream from the anode.

2. The Hall effect thruster of claim 1, further comprising a first shielding element configured to shield the inner sidewall electrode from electrons in the annular discharge channel, and a second shielding element configured to shield the outer sidewall electrode from electrons in the annular discharge channel.

3. The Hall effect thruster of claim 2, wherein the first and second shielding elements comprise first and second magnetic shielding elements.

4. The Hall effect thruster of claim 3, wherein the first and second magnetic shielding elements comprise respective first and second electromagnets configured to generate magnetic fields, portions of which are generally perpendicular to respective surface normal vectors of the inner sidewall electrode and the outer sidewall electrode.

5. The Hall effect thruster of claim 3, wherein the first and second magnetic shielding elements are configured to generate ring cusp magnetic fields.

6. The Hall effect thruster of claim 1, wherein the inner sidewall electrode is embedded within the inner sidewall of the annular discharge channel, and the outer sidewall electrode is embedded within the outer sidewall of the annular discharge channel.

7. The Hall effect thruster of claim 6, wherein the inner sidewall electrode is substantially flush with the surface of the inner sidewall of the annular discharge channel, and the outer sidewall electrode is substantially flush with the surface of the outer sidewall of the annular discharge channel.

8. The Hall effect thruster of claim 1, further comprising a first voltage source that is electrically coupled to the anode so as to bias the anode at a first positive electrical voltage level, and a second voltage source that is electrically coupled to the inner and outer sidewall electrodes so as to bias them at a second positive electrical voltage level that is greater than the first electrical voltage level.

9. The Hall effect thruster of claim 8, wherein the second electrical voltage level is approximately 10 V to approximately 30 V greater than the first electrical voltage level.

10. The Hall effect thruster of claim 8, wherein a positive terminal of the second voltage source is electrically connected to the inner and outer sidewall electrodes, and a negative terminal of the second voltage source is electrically connected to a positive terminal of the first voltage source.

11. The Hall effect thruster of claim 1, wherein the inner sidewall electrode and the outer sidewall electrode comprise graphite.

12. The Hall effect thruster of claim 1, further comprising a magnetic circuit configured to provide a generally radial magnetic field between at least a portion of the inner sidewall and at least a portion of the outer sidewall, wherein the inner and outer sidewall electrodes are located upstream of the peak of the radial magnetic field.

13. The Hall effect thruster of claim 1, wherein the thruster is configured such that the magnitude of the radial component of the total magnetic field within the annular discharge channel during operation is approximately zero at the anode.

14. The Hall effect thruster of claim 1, wherein the inner sidewall electrode comprises a ring disposed about the inner sidewall of the discharge channel, and the outer sidewall electrode comprises a ring disposed about the outer sidewall of the discharge channel.

15. A method of using a Hall effect thruster, the method comprising:
supplying electrons within a discharge channel, the discharge channel comprising an inner sidewall separated from an outer sidewall;
magnetically generating a Hall effect current within the discharge channel using the electrons;
supplying a propellant within the discharge channel;
ionizing the propellant to create ions;
generating a first electric field in the discharge channel by providing an electric potential to an anode in order to accelerate the ions; and
guiding the accelerated ions along a longitudinal axis of the discharge channel.

16. The method of claim 15, wherein guiding the accelerated ions along the longitudinal axis of the discharge channel comprises generating a second electric field in the discharge channel using one or more electrodes in addition to the anode.

17. The method of claim 16, wherein generating the second electric field comprises providing an electrical potential to an inner sidewall electrode and an outer sidewall electrode.

18. The method of claim 17, wherein the electric potential provided to the inner sidewall electrode and the outer sidewall electrode is greater than the electric potential provided to the anode.

19. The method of claim 17, wherein the electric potential provided to the inner sidewall electrode and the outer sidewall electrode is at least 5V greater than the electric potential provided to the anode.

20. The method of claim 19, wherein the electric potential provided to the inner sidewall electrode and the outer sidewall electrode is at least 10V greater than the electric potential provided to the anode.

21. The method of claim 17, wherein the inner and outer sidewall electrodes are located at axial positions that are downstream from the anode.

22. The method of claim 17, further comprising shielding the inner and outer sidewall electrodes from electrons in the annular discharge channel.

23. The method of claim 17, wherein the inner sidewall electrode is embedded within the inner sidewall of the discharge channel, and the outer sidewall electrode is embedded within the outer sidewall of the discharge channel.

24. The method of claim 17, wherein the inner sidewall electrode is substantially flush with the surface of the inner sidewall of the discharge channel, and the outer sidewall electrode is substantially flush with the surface of the outer sidewall of the discharge channel.

25. The method of claim 24, wherein shielding the inner and outer sidewall electrodes comprises magnetically shielding the inner and outer sidewall electrodes.

26. The method of claim 25, wherein magnetically shielding the inner and outer sidewall electrodes comprises generating magnetic fields, portions of which are generally perpendicular to respective surface normal vectors of the inner sidewall electrode and the outer sidewall electrode.

27. A method of manufacturing a Hall effect thruster, the method comprising:
providing a discharge channel comprising an inner sidewall radially separated from an outer sidewall;
providing an anode within the discharge channel;
providing an inner sidewall electrode located at an axial position that is downstream from the anode; and
providing an outer sidewall electrode located at an axial position that is downstream from the anode.

28. The method of claim 27, wherein the inner sidewall electrode comprises a ring disposed about the inner sidewall of the discharge channel, and the outer sidewall electrode comprises a ring disposed about the outer sidewall of the discharge channel.

29. The method of claim 27, further comprising providing a first shielding element configured to shield the inner sidewall electrode from electrons in the annular discharge channel, and providing a second shielding element configured to shield the outer sidewall electrode from electrons in the annular discharge channel.

30. The method of claim 27, wherein the inner sidewall electrode is substantially flush with the surface of the inner sidewall of the discharge channel, and the outer sidewall electrode is substantially flush with the surface of the outer sidewall of the discharge channel.
